(19) United States
(12) Patent Application Publication
(10) Pub. No.: US 2022/0230859 A1
(43) Pub. Date: Jul. 21, 2022

(54) BELLOWS COATING BY MAGNETRON SPUTTERING WITH KICK PULSE

(71) Applicant: Starfire Industries LLC, Champaign, IL (US)

(72) Inventors: Thomas J. Houlahan, JR., Urbana, IL (US); Daniel P. Menet, Urbana, IL (US); Ian F. Haehnlein, Champaign, IL (US); Robert A. Stubbers, Savoy, IL (US); Brian E. Jurczyk, Champaign, IL (US)

(21) Appl. No.: 17/580,585

(22) Filed: Jan. 20, 2022

Related U.S. Application Data
(60) Provisional application No. 63/139,609, filed on Jan. 20, 2021.

(51) Int. Cl. H01J 37/34; C23C 14/35; C23C 14/56

(52) U.S. Cl. CPC H01J 37/3405; C23C 14/56; C23C 14/35

(57) ABSTRACT

A radial magnetron system for plasma surface modification and deposition of high-quality coatings for multi-dimensional structures is described. The system includes an axial electrode, a target material disposed on a portion of the axial electrode, an applied potential from an external electrical power source, and a high-current contact attached to the axial electrode for the applied potential. The system further includes a primary permanent magnet assembly comprising individual magnetic material elements configured to produce a target-region magnetic field for generating a Hall-effect dense plasma region under application of the applied potential to the axial electrode, and a magnet substrate that supports the primary permanent magnet assembly within the axial electrode. The magnet substrate is configured to provide a passageway for cooling the primary permanent magnet assembly and the axial electrode.

### CROSS-REFERENCE TO RELATED APPLICATION

This application is a nonprovisional of U.S. Provisional Application No. 63/139,609, filed Jan. 20, 2021, entitled “Bellows Coating by Magnetron Sputtering with Kick Pulse,” the contents of which are expressly incorporated herein by reference in its entirety, including any references therein.

This application relates to application Ser. No. 16/848,353 which is a continuation-in-part of, and claims the priority of, U.S. application Ser. No. 15/803,320, filed Nov. 3, 2017 (U.S. Pat. No. 10,624,199), entitled “A COMPACT SYSTEM FOR COUPLING RF POWER DIRECTLY INTO RF LINACS,” which is a non-provisional of U.S. Provisional Application Ser. No. 62/416,900, filed Nov. 3, 2016, entitled “A COMPACT SYSTEM FOR COUPLING RF POWER DIRECTLY INTO RF LINACS,” the contents of each of which (of the above-cited applications) are expressly incorporated herein by reference in their entirety, including any references therein.

This application relates to application Ser. No. 16/848,353 which is a continuation-in-part of, and claims the priority of, U.S. application Ser. No. 16/006,357, filed on Jun. 12, 2018, entitled “PULSED POWER MODULE WITH PULSE AND ION FLUX CONTROL FOR MAGNETRON SPUTTERING,” which is a non-provisional of U.S. Provisional Application Serial No. 62/518,362, filed Jun. 12, 2017, entitled “PULSED POWER MODULE WITH PULSE AND ION FLUX CONTROL FOR MAGNETRON SPUTTERING,” the contents of each of which (of the above-cited applications) are expressly incorporated herein by reference in their entirety, including any references therein.

This application relates to application Ser. No. 16/848,353 which is a continuation-in-part of, and claims the priority of, U.S. application Ser. No. 16/801,002, filed Feb. 25, 2020, and entitled “METHOD AND APPARATUS FOR METAL AND CERAMIC NANOLAYERING FOR ACCIDENT TOLERANT NUCLEAR FUEL, PARTICLE ACCELERATORS & AEROSPACE LEADING EDGES,” which is a non-provisional of U.S. Provisional Patent Application No. 62/810,230, filed on Feb. 25, 2019, entitled “METHOD AND APPARATUS FOR METAL AND CERAMIC NANOLAYERING FOR ACCIDENT TOLERANT NUCLEAR FUEL,” the contents of each of which (of the above-cited applications) are expressly incorporated herein by reference in their entirety, including any references therein.

### TECHNICAL FIELD

The disclosure generally relates to injecting power into accelerator devices, and more particularly to relatively compact high-power radio frequency linear accelerator (RF LINAC) systems. Even more particularly, the present additional disclosure, provided in the form of a set of seventeen (17) slides, relates to application of the technology described herein to a system and method for providing extremely high-quality coating on a bellows internal surface.

### BACKGROUND OF THE INVENTION

High-power RF cavities, such as those found in a cryogenic super-conducting radiofrequency (SRF) LINAC, require not only tremendous RF powers (on the order to 10's to 100's of kW and above), but also a vacuum environment to prevent arcing and sparking within the RF cavity due to the intense electric fields associated with such high powers. The RF power needed to reach a specific electric field within the resonant cavity is governed by the quality factor (Q) which is integral energy stored divided by energy lost per cycle. For resonant RF cavities, the formula reduces to

$$Q = \frac{\sqrt{\frac{L}{C}}}{{R}_{surface}} = {( \frac{Δ ω}{{ω}_{o}} )}^{- 1}$$

since the RF energy propagates along the surface and is a function of the surface resistance

$${R}_{surface} = \frac{1}{Conductivity \times Skin Depth}$$

that is proportional to the square root of RF frequency. Higher quality factor leads to higher efficiencies, higher achievable voltages and accelerating gradients. SRF cavities take advantage of very high-quality factors (on the order of 1E8 to 1E9) to achieve extreme accelerating fields with modest power input and modest power consumption. This allows very large scale particle accelerators, such as the Large Hadron Collider at CERN and the Continuous Electron Beam Accelerator Facility at the Thomas Jefferson National Accelerator Laboratory, to operate cost effectively and efficiently. However, there are engineering tradeoffs in cavity design and operation since electrical skin depths are on the order of microns for GHz frequencies. Cryogenic RF cavities, beamlines, bellows and waveguide sections are typically fashioned out of vacuum-grade stainless steel and electroplated with copper for lower surface resistance, or they are constructed out of solid blocks of base material, such as ultra-pure high residual resistivity ration (RRR) niobium, to achieve low-loss superconducting properties. Electroplating and/or machining ultra-pure materials into complex vacuum components for accelerator applications is challenging and costly. As accelerators scale to large sizes to achieve higher energies (e.g. >10 TeV) and devices transition for commercial and industrial applications (e.g. e-beam sources, there is a need to improve the state of the art.

Wet chemical electroplating is being progressively phased out due to its damaging environmental impact, hazardous chemical handling, high cost, and lack of experienced tradespeople in the field. In the EU there are proposals and timelines for the complete phase out of all electroplating in the coming years, making investment in alternative technologies important. Years of attenuation have left only a small handful companies in the US that perform such coatings. Often multiple customer parts will be run using the same tanks, electrodes, and recirculating chemical baths creating embedded impurities, non-conformal deposition and delamination leading to scrapped assemblies, rework, additional cost, and timeline growth. Replacing error-prone wet chemical plating with a physical vapor deposition process is one method. However, it was difficult and challenging to treat the interior of components and three-dimensional surfaces.

Furthermore, superconducting fields are only conducted on the surface of materials due to the skin depth effect. Machining entire structures from a solid billet of ultra-pure material is a major waste and cost driver when it is desirable only to deposit or coat vacuum surfaces with thin-layers of superconducting materials and engineer the SRF properties. The reason that large-area, conformal, SRF coatings are of particular interest to the accelerator community is that they can be used to build SRF cavity structures having properties equivalent or even superior to the bulk-Nb elliptical cavities presently in use and at a potentially lower cost. In some cases, the interest is in replacing Nb cavities with Nb-coated Cu both for cost reduction and for an improvement in thermal handling properties, while in other cases, the focus is on exceeding the bulk Nb RF and/or thermal performance through the use of other materials (e.g. Nb3Sn coatings) and/or multilayered structures. A significant challenge here lies in the deposition of SRF films onto these cavities: film deposition onto a curved, complex surface is considerably more difficult than film deposition onto a wafer or test coupon, especially where the film parameters (e.g. thickness) are required to fall within a set window over the entire cavity structure. This is especially true for multilayer (e.g. SIS) structures, where small variations in layer thicknesses can have a profound effect on the end result. Further complicating the overall process is the inclusion of particles and defects within the film, whether introduced before, during, or after the coating process. The result of these inclusions is a degradation—which is often extreme—in the overall performance of the film.

The current disclosure uses conformal ionized physical vapor deposition (iPVD) to replace wet chemical electroplating (e.g. Cu) for stainless-steel bellows and other specialty vacuum components used on accelerator structures.

### SUMMARY OF THE INVENTION

The disclosure is directed to a radial magnetron system for plasma surface modification and deposition of high-quality coatings for multi-dimensional structures is described. The system includes an axial electrode, a target material disposed on a portion of the axial electrode, an applied potential from an external electrical power source, and a high-current contact attached to the axial electrode for the applied potential. The system further includes a primary permanent magnet assembly comprising individual magnetic material elements configured to produce a target-region magnetic field for generating a Hall-effect dense plasma region under application of the applied potential to the axial electrode, and a magnet substrate that supports the primary permanent magnet assembly within the axial electrode. The magnet substrate is configured to provide a passageway for cooling the primary permanent magnet assembly and the axial electrode.

The disclosure is further directed to a batch coating system for depositing high-quality films on multiple surface treatment structures is also described. The system includes a vacuum chamber assembly, a radial magnetron including a target material, an external electrical power source, and a mounting structure to hold multiple surface treatment structures. The mounting structure is interposed between the radial magnetron and the vacuum chamber. During operation, the multiple surface treatment structures are treated using plasma generated in a plasma generating zone proximate the radial magnetron. Furthermore, the external electrical power source further comprises field-generating electronic circuitry configured to perform: generating a high-power pulsed plasma magnetron discharge with a high-current negative direct current (DC) pulse applied to the axial electrode, and generating a configurable sustained positive voltage kick pulse provided to the axial electrode after terminating the negative DC pulse. During the generating, program processor configured logic circuitry issues a control signal to control at least one kick pulse property of the sustained positive voltage kick pulse taken from the group consisting of: onset delay, duration, amplitude, and frequency including modulation thereof.

The disclosure is further directed to a roll-to-roll web coating system for depositing high-quality films simultaneously on multiple flexible substrate surfaces from a single radial magnetron. The system includes a vacuum chamber assembly, a radial magnetron including a target material, an external electrical power source; and a roll-to-roll web conveyance system for simultaneously transporting a substrate into a plasma treatment zone. During operation, the radial magnetron generates a plasma field for creating the plasma treatment zone. The external electrical power source further includes field-generating electronic circuitry configured to perform: generating a high-power pulsed plasma magnetron discharge with a high-current negative direct current (DC) pulse applied to the axial electrode, and generating a configurable sustained positive voltage kick pulse provided to the axial electrode after terminating the negative DC pulse. During the generating, program processor configured logic circuitry issues a control signal to control at least one kick pulse property of the sustained positive voltage kick pulse taken from the group consisting of: onset delay, duration, amplitude, and frequency including modulation thereof.

Additional features and advantages of the invention will be made apparent from the following detailed description of illustrative examples that proceeds with reference to the accompanying figures.

### BRIEF DESCRIPTION OF THE DRAWINGS

While the appended claims set forth the features of the present invention with particularity, the invention, together with its objects and advantages, may be best understood from the following detailed description taken in conjunction with the accompanying drawings of which:

FIG. 1A is an axial schematic drawing of a radial magnetron system suitable for incorporating the features of the disclosure;

FIG. 1B is a cross-sectional schematic drawing of a radial magnetron system suitable for incorporating the features of the disclosure;

FIG. 1C is a photograph of a radial magnetron system in operation under IMPULSE+Positive Kick HiPIMS operation without magnetic rotation;

FIG. 1D is a photograph of a radial magnetron system in operation under IMPULSE +Positive Kick with magnetic rotation under etch-like process parameters;

FIG. 1E is a photograph of a radial magnetron system in operation under IMPULSE+Positive Kick with magnetic rotation under deposition-like process parameters;

FIG. 2A depicts a side sectional view along the axis of a high-current radial magnetron system with an internally-rotating primary sputter/etch permanent magnet assembly generating a moving target-region magnetic field coupled to an air-side external magnetic drive;

FIG. 2B depicts a side sectional vies of an illustrative solid model view of a radial magnetron with internal flow channels, primary magnetic placement on the vacuum-side for sputtering/etching, secondary magnetic placement on the air-side for independent magnetic rotation, and PTFE bushings for rotation, and insulators;

FIG. 2C is a photograph of a high-current radial magnetron system with rotating magnetic field operating with IMPULSE® +Positive Kick™ for sputter etch/deposition with copper;

FIG. 3 depicts a cross-sectional view of an illustrative example of a radial magnetron system where the primary sputter/etch permanent magnet assembly partially encircles the circumference of the radial magnetron thereby constraining the dense plasma regions to discrete regions that move under rotation and/or axial displacement;

FIG. 4A schematically depicts a sectional view along the axis of a high-current radial magnetron system with the vacuum-side primary sputter/etch permanent magnet assembly capable of axial-displacement generating a moving target-region magnetic field coupled to an air-side external magnetic drive;

FIG. 4B further depicts the axial displacement of the primary sputter/etch permanent magnet assembly in a radial magnetron configured for axial movement of the target-region magnetic field to generate dense plasma regions for sputtering and etching;

FIG. 4C is a photograph of a high-current radial magnetron operating under IMPULSE®+Positive Kick™ employing a primary sputter/etch permanent magnet assembly capable of axial-displacement;

FIG. 5A is an illustrative example of the construction of a large radial magnetron axial cylindrical electrode with multiple externally-facing target material sections for the sputter/etch of a long substrate;

FIG. 5B is a photograph highlighting segmented niobium targets bonded to a copper axial electrode using a thermal shrink fit assembly technique;

FIG. 5C is a photograph of a meter-long radial magnetron target-bonded electrode prior to assembly with internal magnetic assemblies and coolant flow structure;

FIG. 6A illustratively depicts the formation of deep ‘V’ grooves from sputtering the target material surface without magnet-target rotation;

FIG. 6B is a photograph of a radial magnetron after operation without magnet-target rotation showing the deep “racetrack” pattern of target erosion and non-uniformity;

FIG. 6C illustratively depicts a more uniform target material erosion pattern on the target surface resulting from magnet-target rotation (relative movement between the dense plasma regions and sputter target material) and the elimination of deep ‘V’ grooves for better utilization and process uniformity;

FIG. 6D is a photograph of a radial magnetron after operation with magnet-target rotation showing uniform target erosion, elimination of deep ‘V’ grooves, and increased target utilization;

FIG. 7A is a photograph of the prior art showing copper electroplating and discolorations due to embedded defects and impurities from the plating solution on a stainless-steel hydroformed vacuum bellows for cryogenic particle accelerator applications;

FIG. 7B is from the prior art depicting regions in a large-scale superconducting RF particle accelerator cryogenic module where high-purity PVD coatings could be utilized, i.e. long spool, short bellows, long bellows, beamline sections, SRF elliptical cavities, etc.;

FIG. 7C is from the prior art showing RF power loss and thermal dissipation due to poor electrical conductivity with electroplated copper showing the temperature increase in a cryogenically-cooled vacuum bellows section for two different RRR values vs. coating thickness highlighting the need for high-purity thin-film coatings;

FIG. 7D is a prior art photograph of embedded defects and impurities from the electroplating copper solution and the impact on a stainless-steel bellows;

FIG. 7E is a prior art summary of defect materials and sizing in typical electroplated copper used in particle accelerator applications that have some contribution to the lower RRR, surface defects that can lead to sparking and electron emission under high electric fields, and poor performance;

FIG. 8A depicts a comparison between conventional DC sputtering, pulsed DC, traditional HiPIMS and IMPULSE®+Positive Kick™;

FIG. 8B is an illustrative pulse waveform highlighting the specific features of the IMPULSE®+Positive Kick™, specifically the intense, high current main negative pulse region generating significant target sputtering and ionization of target material, the Positive Kick™ voltage reversal that expels plasma from the target-region magnetic field in the form of energetic ions (short kick) and bulk plasma transport to the substrate (long kick)—the oscilloscope waveform is a Cu plasma achieving 2 kA peak current in 20 microseconds with subsequent +200V positive pulse for 50 microseconds;

FIG. 9A depicts an illustration of the 1^{st} of 3 phases during an IMPULSE pulse operation—the Ultra-Fast HiPIMS phase;

FIG. 9B depicts an illustration of the 2^{nd} of 3 phases during IMPULSE operation—the Short Kick phase;

FIG. 9C depicts an illustration of the 3^{rd} of 3 phases during IMPULSE operation—the Long Kick phase;

FIG. 10 depicts an illustration of a continuous process using the IMPULSE®+Positive Kick™ without breaking vacuum, interruptions or staging;

FIG. 11A is an illustration depicting the effects of the IMPULSE®+Positive Kick™ at a substrate that exhibits 3D or high-aspect features, including energetic ion bombardment from the short kick phase, substrate immersion in bulk plasma expansion with subsequent quasi-conformality and ion bombardment from the long kick phase;

FIG. 11B is a photograph of high-aspect ratio stainless-steel bellows sections in a traditional W and Ω shape treated with a Radial Magnetron™+IMPULSE®+Positive Kick™ demonstrating quasi-conformal Cu coverage, having high strength and surviving cryogenic immersion, heat treatment, plastic deformation stretching, and cyclic fatigue without buckling, delamination or film failure;

FIG. 11C is a photograph of a stainless steel hydroformed bellows section coated on the inner diameter with an insertable Radial Magnetron using IMPULSE®+Positive Kick™ HiPIMS etching and deposition;

FIG. 11D is another photograph down the inner bore of the same bellows from FIG. 11C highlighting the uniformity of coverage;

FIG. 11E is a photograph of a wire-EDM destructive test to cross-section the copper coating showing continuous coverage and no material failures of the bellows depicted in FIGS. 11C and 11D;

FIG. 12 depicts a high-level schematic representation of the thin-film deposition, etch and surface modification system with IMPULSE® pulse modules and power supplies;

FIG. 13A is a photograph of an IMPULSE® pulse module and related power supplies;

FIG. 13B is a schematic illustration of a single radial magnetron in-line deposition system for the surface modification, etch and deposition of vacuum bellows and accelerator components incorporating/using the IMPULSE® pulse module/operation;

FIG. 13C is a schematic illustration of a multiple radial magnetron in-line deposition system for the surface modification, etch and deposition of an example Cu cavity for a superconducting coating comprised of more than one material, e.g. radial magnetron A and radial magnetron B;

FIG. 14A is a side-profile schematic illustration of a radial magnetron batch deposition system comprising a vacuum chamber, at least one radial magnetron, and at least one substrate mounting structure interposed between the radial magnetron and the vacuum chamber wherein substrates are etched or deposited with plasma and material generated at or near the radial magnetron;

FIG. 14B is a top-down schematic illustration of a radial magnetron batch deposition system highlighting placement of one or more radial magnetrons, multiple substrate mounting structures, auxiliary anodes, and the vacuum chamber boundary;

FIG. 14C is a side-profile schematic illustration of a radial magnetron batch deposition system highlighting an exchange system for insertion/extraction of multiple radial magnetrons, shield covers, and auxiliary anodes;

FIG. 15 is a schematic illustration of the application of a radial magnetron to a traditional in-line conveyance substrate processing station highlighting the IMPULSE®+Positive Kick™ enhanced plasma transport to the substrates;

FIG. 16A is a schematic illustration of the application of a radial magnetron for in-line roll-to-roll and web coating where the substrate is transported relative to the radial magnetron and can be guided proximal to the radial magnetron for greater utilization efficiency;

FIG. 16B further depicts the application of multiple radial magnetrons to provide high-rate continuous coating of roll-to-roll thin-films and potential addition of auxiliary anode return electrodes for insulating or large-area substrates;

FIG. 16C further depicts the routing of a flexible substrate around a single radial magnetron to maximize the utilization of sputtered material, and can be daisy chained with additional radial magnetrons for multi-layer coatings and in-line radial magnetron swap;

FIG. 17 illustratively depicts an example structure zone diagram with two independent axes for effective temperature (T*) and effective sputter particle energy (E*) that are addressable with the IMPULSE® and Positive Kick™.

### DETAILED DESCRIPTION OF THE DRAWINGS

The detailed description of the figures that follows is not to be taken in a limiting sense, but is made merely for the purpose of describing the principles of the described embodiments.

Traditional structures and systems for fabricating superconducting radio-frequency (SRF) accelerator systems involve taking a large billet of special grade material or alloys, such as niobium metal, beryllium metal, ultra-high purity oxygen-free copper, and precision machining to precise dimensional tolerance for narrow frequency band resonant cavities for RF acceleration. For many accelerator components, only a very small fraction (i.e. a few percent) of the bulk material is used—with a significant amount of lost material, time and labor. This is done at great cost to preserve material properties; and to minimize lossy interfaces, tolerance/stack-up errors, hermetic breaks and mismatches. Often a substrate material is used for its superior structural properties at a performance cost of electrical or thermal properties. Tradeoff choices include: using stainless steel instead of copper, or the converse selection of niobium instead of copper. Because electrical properties dominate in the skin-depth for electromagnetic propagation in materials at high-frequencies (e.g. MHz), using a composite structure with a surface layer that exhibits superior electrical and vacuum properties. For wet chemical processes, such as electroplating, there are challenges in terms of coating thickness uniformity, impurities in the solution, sacrificial anodes, irreproducibility from batch to batch, and material supply purity. This is particularly challenging for copper onto stainless steel used at cryogenic temperatures simply to minimize resistive loss over hundreds of meters of vacuum systems, accelerator beamlines, and transport tubes.

With a composite structure, different materials may be selected for different components for thermal characteristics, structural support, expansion and contraction, anti-vibration, etc. With the ability to form composite structures, novel methods for fabrication, alignment, fixturing, and segmentation facilitates reducing cost and improving design flexibility for weight, size and power reduction and ease of integration. In particular, desirable surface material properties (e.g. low electron emission), material purity (e.g. low inclusions, low field concentration), cavity smoothness (e.g. lower field emission, higher gradient), near-surface morphology (e.g. limited whisker growth, spark initiation), and vacuum tolerance (e.g. low vapor pressure, surface mobility) can be engineered to improve the characteristics of the RF LINAC.

The manufacturing operations and techniques described herein also allow replacing bulk, solid niobium materials with thin-layers for superconducting cavities using more robust, thermally conductive and easier to form/machine/work materials-or can replace environmentally challenging wet chemistry techniques altogether. Because of the diversity of materials that can be deposited onto a range of substrates, the technique allows more options and choices for accelerator cavities and components. Conventional wet chemistry and electroplating techniques are limited in substrate material choices, substrate shape, contamination, surface material finish, and adhesion strength. The presently disclosed innovative fabrication features described herein are based on use of conformal physical vapor deposition in combination with surface etching, preparation and modification techniques for a wide range of materials.

Physical-vapor deposition (PVD) coatings can be tailored to produce desired physical, thermal, and electronic properties—particularly considering the new IMPULSE®+Positive Kick™ high-power impulse magnetron sputtering (HiPIMS) techniques that provide precision ion energy control and deposition rate improvements. See U.S. Pat. No. 11,069,515 and related applications. However, PVD coatings on the inner diameter of small pipes or complex shapes, such as 3D bellows, elliptical SRF cavities and beam shaping elements, has been challenging due to limitations on the physical PVD sputtering hardware physically fitting into the space, providing sufficient uniformity, limiting dust/particles/arcing, and managing multiple materials. Standard magnetron sputtering is accomplished with planar rectangles for large area or planar circular magnetrons for small area coatings. These systems typically achieve 15-40% target utilization and are used in in-line production for glass windows, solar panels, and semiconductor coatings. An improvement in target utilization is achieved by rotating cylindrical targets about a fixed planar rectangular magnetic field to increase utilization to 90% with a directional sputtering process (i.e. sputter down). However, these shapes are highly limited for precision coating on the inner dimension of components, especially objects less than 0.5 m diameter.

The innovation in this disclosure specifically pertains to a novel radial magnetron configuration that combines cylindrical target material geometry, suitable for small size and long length, with a movable permanent magnetic structure within the cylindrical target material geometry which can move localized target-region magnetic fields around the target surface to produce dense plasma regions for etching and sputtering. The cylindrical shape is ideal to fit into small diameters for small ID coatings, as well as be extended to larger diameters for batch coating applications.

The illustrative examples described herein differ from use of the cylindrical post magnetron developed over 30 years ago that uses a set of large external electromagnets to produce a uniform axial B-field volume to setup Hall currents for sputtering. The radial magnetron of the present disclosure uses high-gradient (cusp-like) fields near the target surface with internal permanent magnets to control and limit dense plasma regions suitable for HiPIMS operation. Movement of the magnetic field through rotation or axial displacement enables target uniformity. Further, the conventional cylindrical cathode magnetrons widely used in semiconductor and web-coating industries employ physically-rotating targets electrodes with brushed electrical contacts unsuitable for pulsed current handling capabilities for HiPIMS operation. Starfire's technology has hard metal contacts that can handle currents far in excess of what is typical of HiPIMS operation, the ability for positive voltage reversal, and rotating plasma regions for uniformity. The ultra-fast IMPULSE® technology can routinely push current densities >10 A/cm2 (which is more than 10× standard HiPIMS) leading to >90% ionization rates for directed iPVD. The hard, high current contact enables this feature with the rotating/displacement permanent magnetic assembly. Additionally, particle generation is further minimized by the fact that none of the vacuum facing surfaces/components move; only the radial magnetron internal magnet assembly, which does not see vacuum, is rotating or moving. This is critical for many thin-film applications.

Accelerator machines are large, costly and are typically found at national laboratories, medical centers, and research universities. Direct sputter coating on the interior can seal the interfaces between components, such as vanes, spacers, tuning rods, bellows, etc. However, the sputter coating methods and structures described herein are broadly applicable to a variety of applications beyond coating the interior surfaces of accelerator components. Coating the ID of production tubing for oil and gas applications to resist corrosion and erosion, coating gun barrels for wear resistance, etc. The present disclosure also can be used for coating 3D turbine blades for thermal protection, coating 3D cutting tools with hard layers, roll-to-roll web coatings for polymer metallization, in-line glass substrate coatings, etc.

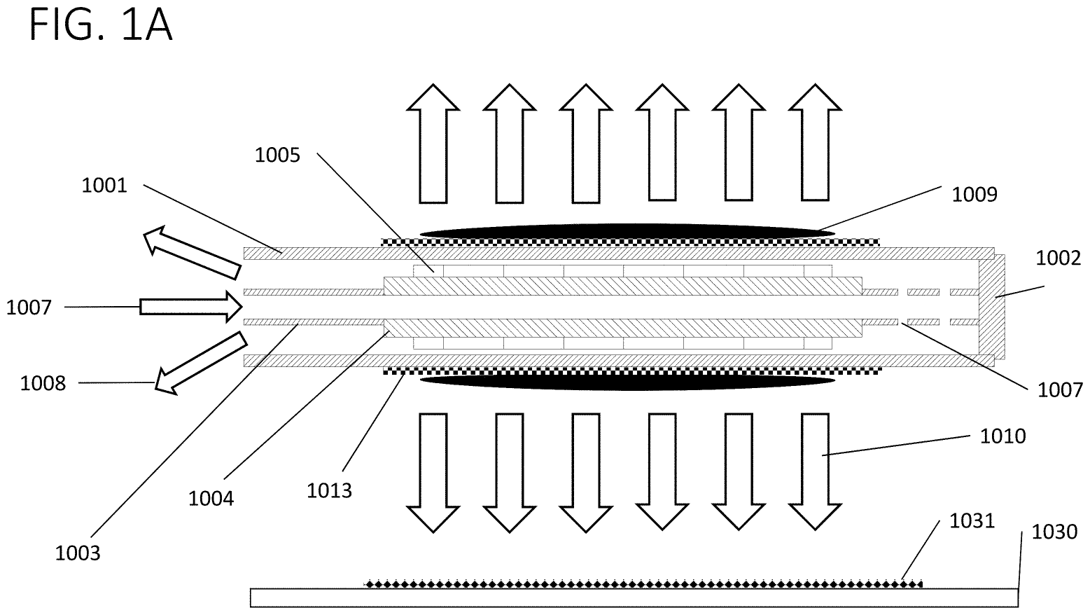

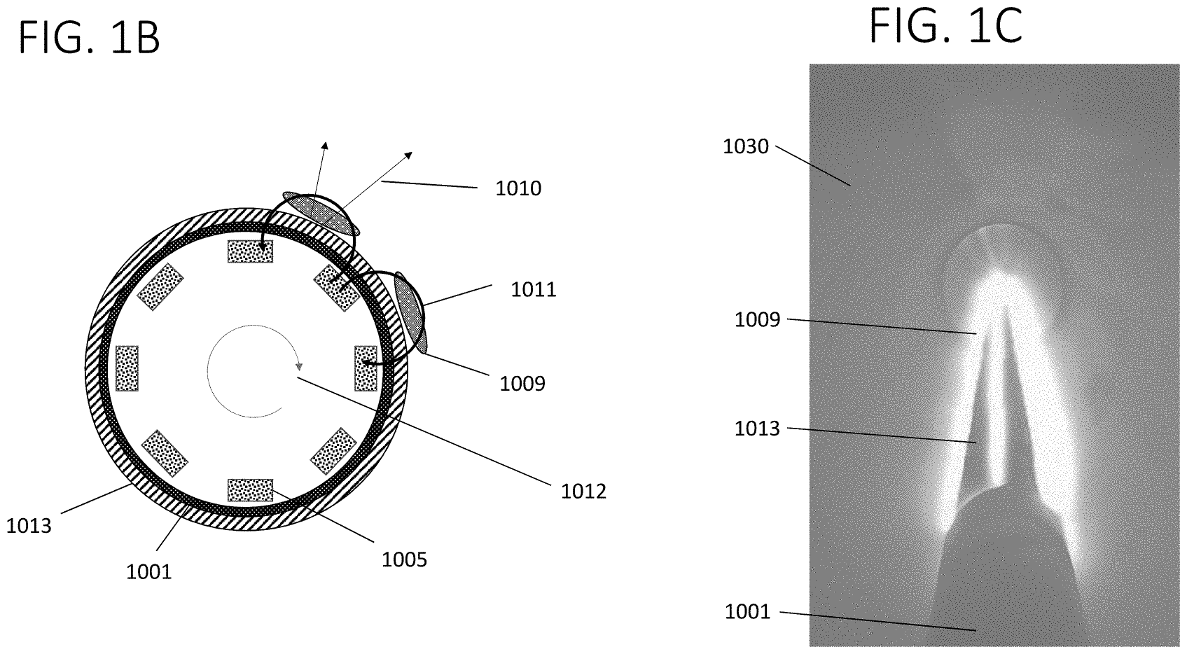

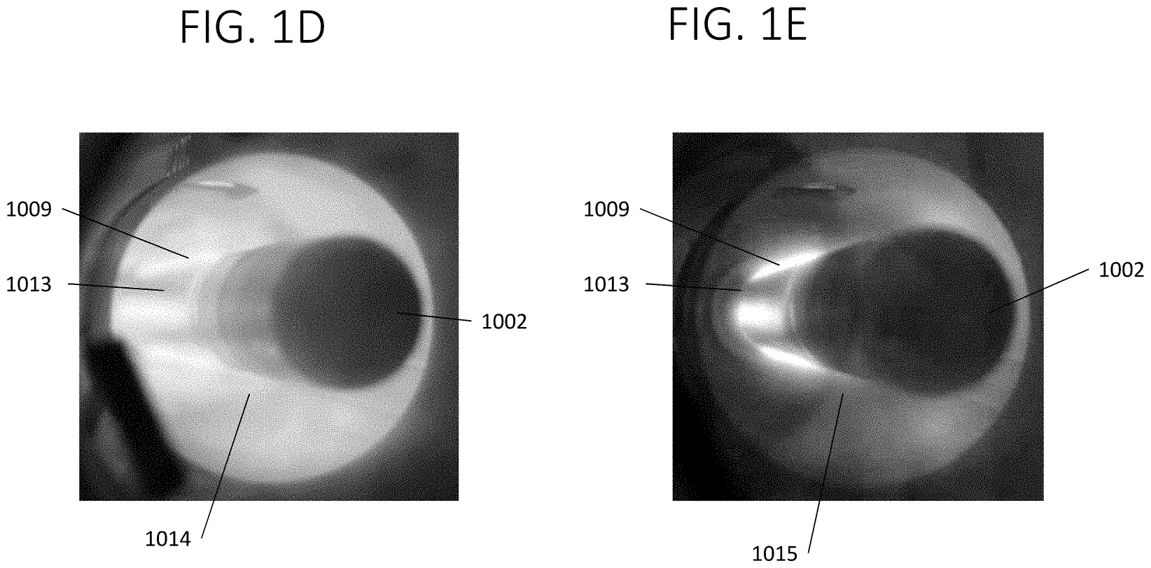

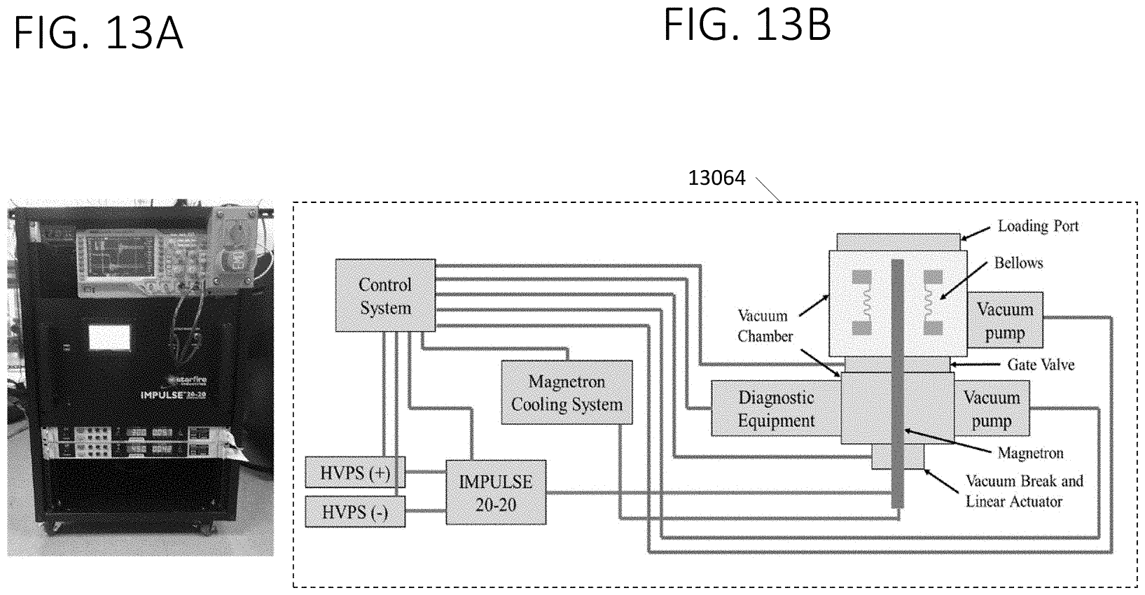

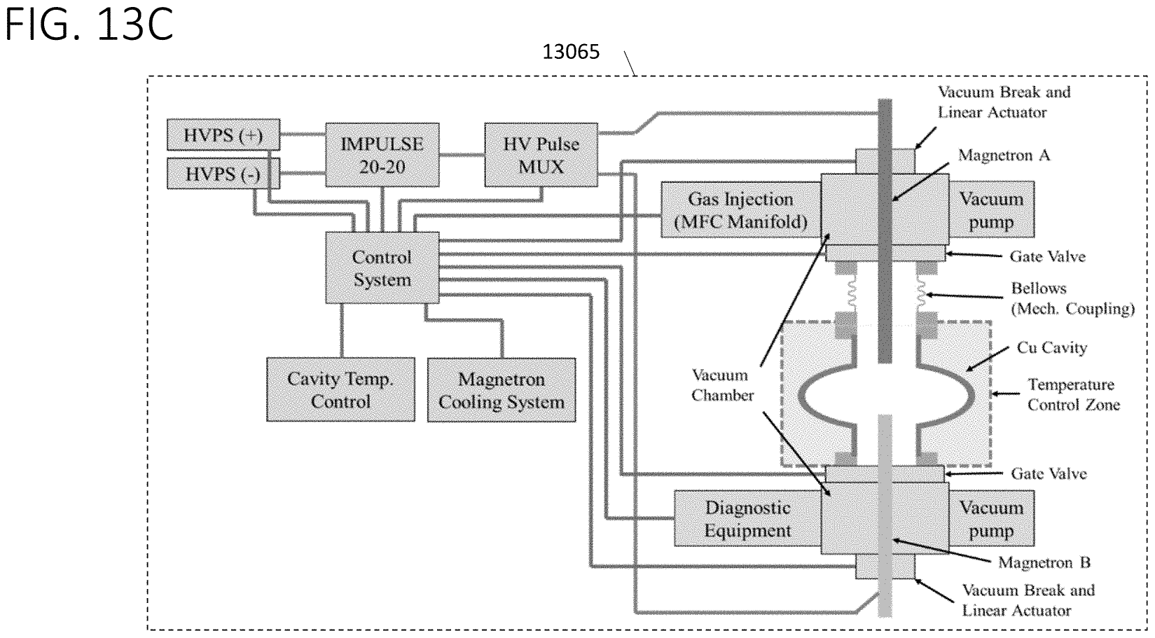

A cross section of such exemplary radial magnetron is shown in FIG. 1A. The illustrative example has all cooling, mechanical, and electrical connections at one end, such that a cylindrical part (e.g., a bellows or tube section) can be easily placed around the magnetron, as shown later in FIG. 13B. Further, it employs a rotating internal magnet pack that has the effects of 1) dramatically improving target utilization and 2) minimizing drift in operating parameters as the target ages.

FIG. 1A is an axial schematic drawing of a radial magnetron system suitable for incorporating the features of the present disclosure. FIG. 1A illustratively depicts an axial internal side cross-sectional view of an end-capped radial magnetron emitting ions and neutrals highlighting internal coolant flow, magnetic assemblies and plasma generation on the exterior. Sputtering target axial electrode 1001 is mounted with an internal cooling channel 1007 flowing coolant over individual permanent magnet materials, such as NdFeB or SmCo, comprising and forming a primary sputter/etch permanent magnet assembly 1005. A sputtering target material 1013 is placed on the exterior of the axial electrode 1001. There may be a magnetic substrate 1004 holder serving as structural support, magnetic flux yoke/shunting and physical spacing of individual permanent magnets to form the primary sputter/etch permanent magnetic assembly 1005. The primary sputter/etch permanent magnet assembly is configured to generate Hall-Effect electron trapping regions proximal to the target material 1013 to generate and sustain a dense plasma region 1009 under the application of a potential to the axial electrode. The cooling fluid input 1007 and cooling fluid exit 1008 provide a means to directly cool the target material 1013 through the axial electrode 1001 and the primary sputter/etch permanent magnet assembly 1005. This is necessary to maintain the magnetic flux density of the target-region magnetic field for suitable plasma formation for sputtering and etching with the application of voltages to the axial electrode 1001. The axial electrode 1001 can be hollow and run across a vacuum chamber through two ports, or it can have an endcap 1002 on one end making the radial magnetron a one-sided device that can be inserted into a vacuum chamber from one port. Furthermore, the primary sputter/etch permanent magnet assembly 1005 can be mounted to a structure that facilitates rotation or movement, such as the internal coolant channel 1003 or other such implantation. The rotation or movement of the magnet-target magnetic field serves to distribute the dense plasma regions 1009 around the axial electrode 1001 to balance the erosion and removal of the target material 1013.

FIG. 1B is a cross-sectional schematic drawing of a radial magnetron system suitable for incorporating the features of the invention. It depicts, in an orthogonal cross-sectional view of the structure depicted in FIG. 1A, a sputtering axial electrode 1001 with target material 1013 in relative motion above a primary sputter/etch permanent magnet assembly 1005 highlighting the relative rotation. The magnet-target rotation 1012 allows target-region magnetic fields 1011 from the magnetic material within the primary sputter/etch permanent magnet assembly 1005 to move relative to the target material 1013 and shift the dense plasma regions 1009 around/along the circumference of the target material 1013 and generate particle flux 1010 used to treat a substrate 1030 (not shown). In the illustrative example, the primary sputter/etch permanent magnet assembly 1005 is mounted to a magnet substrate 1004 that holds the individual magnetic materials in an orientation to generate the Hall-Effect volumes close to the target material 1013 where the dense plasma region 1009 forms. The dense plasma region 1009 generates energetic ions and neutral particle flux 1010 that are directed outward from the sputtering target material 1013 towards the surfaces to be coated, etched and modified.

FIG. 1C is a photograph of a radial magnetron system in operation under IMPULSE +Positive Kick HiPIMS operation without magnetic rotation. The photograph depicts a 1.5-meter long axial electrode 1001 embodiment with a magnetic field arranged to create a single serpentine dense plasma region 1009 around a sputtering target material 1013. Electrons orbit the continuous serpentine racetrack via Hall Effect ExB forces (aka “the magnetron effect”) from the application of voltage on the sputtering target axial electrode 1001, resulting in generation of an intense plasma zone at the dense plasma region 1009. Because it is a single racetrack, the plasma density can load balance over the radial magnetron surface for better uniformity over the length. In this specific example, a 1.5 m-long plasma region is formed with good uniformity over the length suitable for azimuthal rotation. FIG. 1C shows merely an illustrative, non-limiting example of a single continuous radial magnetron without an end cap and can be supported across a vacuum chamber from both sides with power injection on both sides for greater power handing capability.

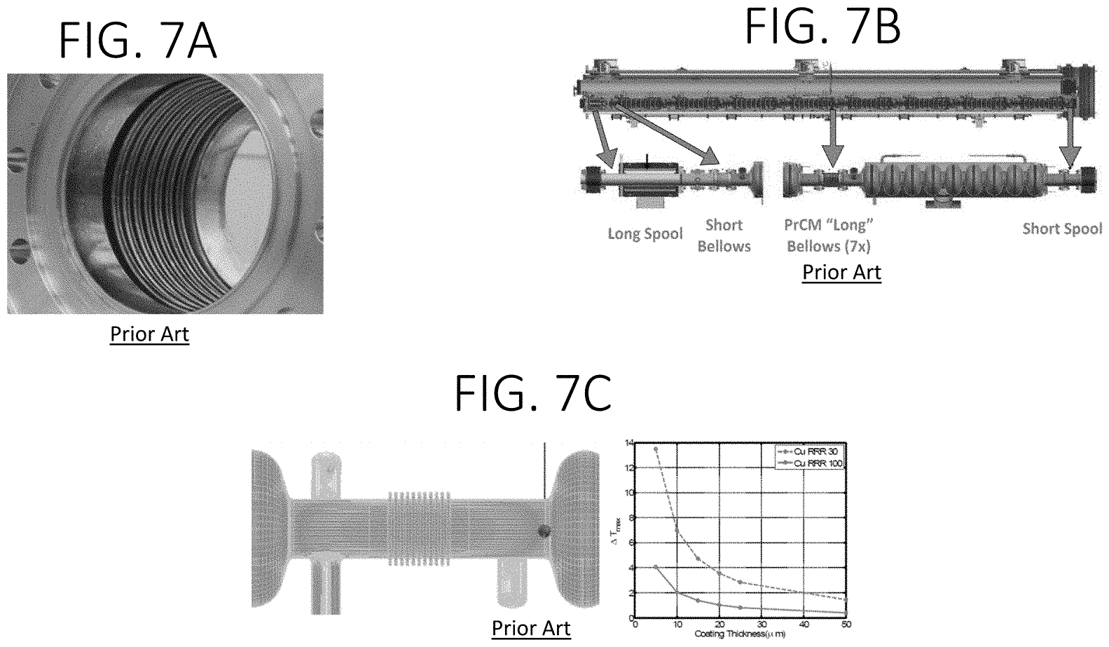

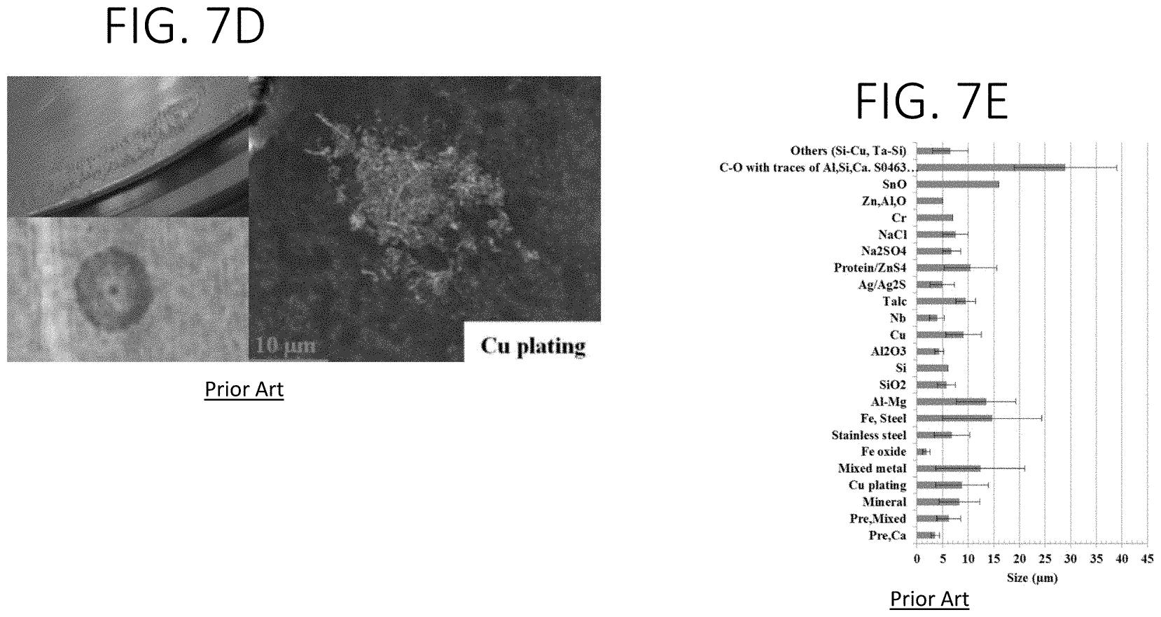

FIG. 1D is a photograph of a radial magnetron system in operation under IMPULSE +Positive Kick with magnetic rotation under etch-like process parameters. This is another embodiment with an end-capped radial magnetron 1002 operating with a single serpentine racetrack dense plasma region 1009 on the sputtering target electrode 1013. In FIG. 7D, the end-capped radial magnetron 1002 employs the IMPULSE®+Positive/Super Kick™ technique for generating an electromagnetic field for performing cleaning, etching and surface modification—as evidenced (when viewed live in operation) by a Etching Mode Plasma 1014 blue-pink-purple color on the copper sputtering target electrode. In this etching mode plasma 1014, the end-capped radial magnetron 1002 generates high energy Ar+ ions and directs the ions radially outward to clean the surface of objects (e.g. an accelerator cavity wall or bellows high-aspect ratio feature) to be processed.

FIG. 1E is a photograph of a radial magnetron system in operation under IMPULSE+Positive Kick with magnetic rotation under deposition-like process parameters. Advantageously, during a surface processing and treating operation, within less than a second, IMPULSE® operational parameters can be changed to switch operation of the assembly from performing a cleaning/etching operation to deposition/implantation operations. FIG. 1E is a photograph of the same system shown in FIG. 1D employing the IMPULSE®+Positive Kick™ technique for generating an electromagnetic field for performing implantation, intermixing, adhesion, stress control, morphology control, diffusion barriers and capping layers—as evidenced (when viewed live in operation) by a bright green copper plasma color for Deposition Mode Plasma 1015 from the sputtering target electrode.

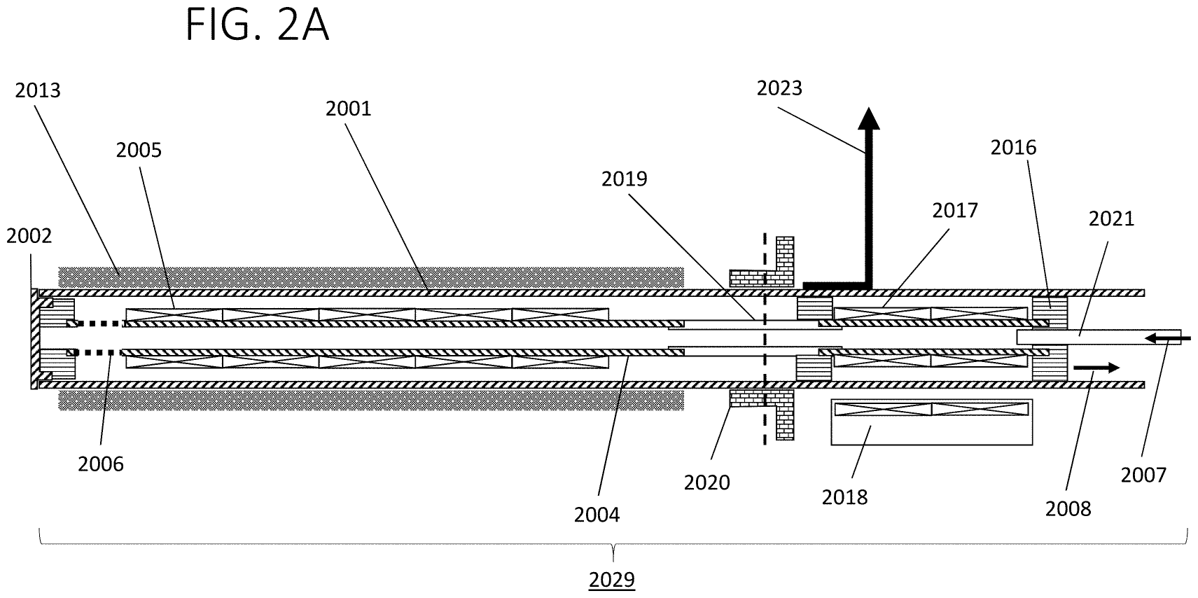

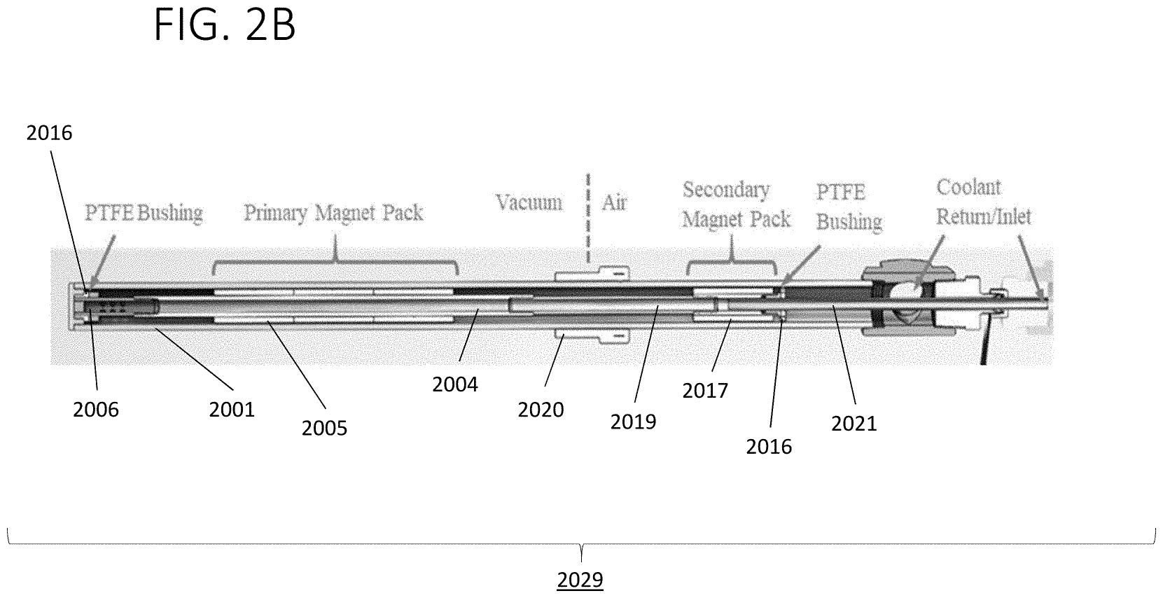

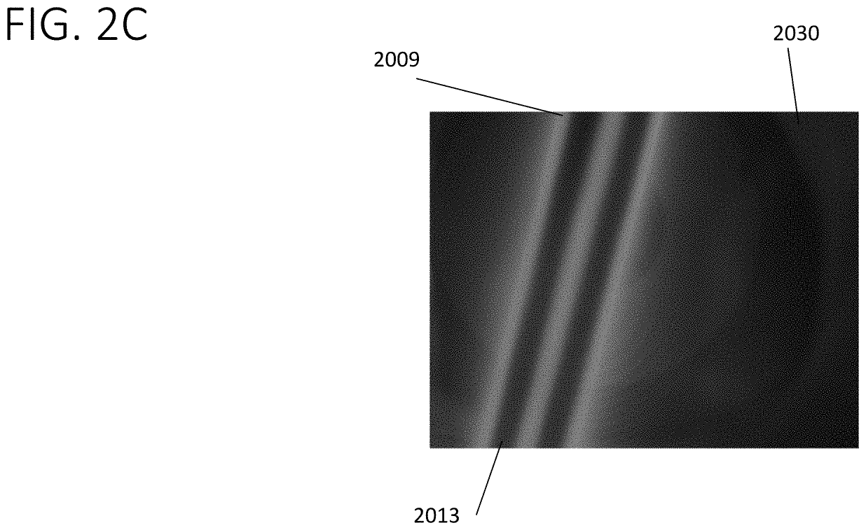

FIG. 2A depicts an sectional view along the axis of a high-current radial magnetron system with an internally-rotating primary sputter/etch permanent magnet assembly generating a moving target-region magnetic field coupled to an air-side external magnetic drive. The primary sputter/etch permanent magnet assembly 2005 is mounted to a magnet substrate 2004 that can serve as an interior coolant passageway from a cooling input tubing 2021 producing input flow 2007. The flow turn around is facilitated by a coolant transition or perforation 2006 to then pass over the axial electrode 2001 internal surface while passing through slotted bushings 2016 that maintain concentric orientation and allow rotation of the primary sputter/etch permanent magnet assembly. A sputtering target material 2013 is affixed to the axial electrode 2001 and if the radial magnetron 2029 is an “end-type” confirmation, an end-cap 2002 closes off the unit. A high-current return line 2023 is attached to the axial electrode with hard contact and high-surface area for good electrical conductivity under pulsed operation for IMPULSE®+Positive Kick™ HiPIMS. A secondary internal motion permanent magnet assembly 2017 is mounted to the magnet substrate 2004 to provide magnetic coupling to the primary sputter/etch permanent magnet assembly 2005 via physical and/or magnetic connection. A secondary external motion permanent magnet assembly 2018 is placed external to the secondary internal motion permanent magnet assembly 2017 and isolated with insulating materials sufficient to protect against high-voltage conditions proximal to the high-current return line 2023. The secondary external motion permanent magnet assembly 2018 can be physically rotated with external actuation such as a belt drive or stepper motor with suitable gears (not shown) to rotate the magnetic assembly to achieve the desired motion on the primary sputter/etch permanent magnet assembly 2005. Again, the high-current return line 2023 provides robust pulse current capability with additional length of the axial electrode 2001 on the air-side of the external isolation/vacuum seam 2020. An external isolation/support 2019 can be used to galvanically isolate the primary sputter/etch permanent magnetic assembly 2005 from the secondary internal permanent magnet assembly 2017, as well as allow for separate components for fabrication regardless of axial electrode 2001 length. Note an external isolation/vacuum seal 2020 can be used to fixture the radial magnetron 2029 into the vacuum system for operation.

FIG. 2B depicts an illustrative solid model of a radial magnetron with internal flow channels, primary magnetic placement on the vacuum-side for sputtering/etching, secondary magnetic placement on the air-side for independent magnetic rotation, and PTFE bushings for rotation, and insulators. Again, coolant input tubing 2021 feeds through a PTFE slotted bushing 2016 into a secondary internal magnetic assembly 2017 affixed to a magnetic substrate 2004 and possibly an internal isolation/support 2019 for galvanic isolation and/or coolant transition or perforation 2006. An axial electrode 2001 runs the entire length of the radial magnetron 2029 through the external isolation/vacuum seal 2020. A further embodiment (not shown) is to place the entire radial magnetron 2029 into a vacuum chamber with a protective layer or casing over the “air side” components and use flexible electrical cabling and hoses for power and coolant.

FIG. 2C is a photograph of a high-current radial magnetron system shown in FIG. 2B with rotating magnetic field operating with IMPULSE®+Positive Kick™ for sputter etch/deposition with copper. The dense plasma region 2009 rotates relative to the target material 2013 and etch/deposit materials onto the substrate 2030 in the distance.

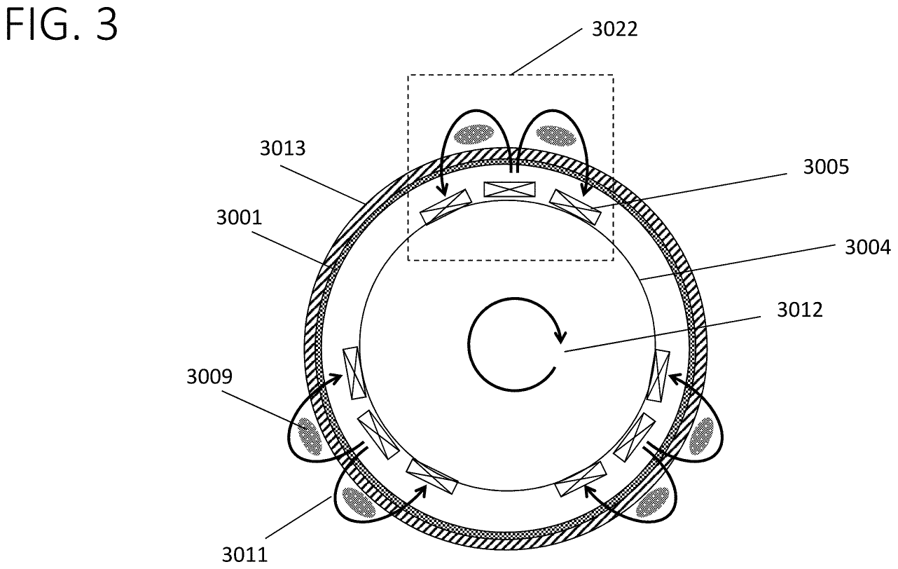

FIG. 3 depicts a cross-sectional view where the primary sputter/etch permanent magnet assembly partially encircles the circumference of the radial magnetron thereby constraining the dense plasma regions to discrete regions that move under rotation and/or axial displacement. The primary sputter/etch permanent magnet assembly 3005 is segmented into discrete individual magnetic-plasma regions 3022 and mounted on a common magnet substrate 3004 that undergoes magnet-target rotation 3012. The dense plasma regions 3009 formed by target-region magnetic field 3011 within each individual magnetic-plasma region 3022 will sputter target material 3013 from axial electrode 3001. By using smaller individual magnetic-plasma regions 3022, the active plasma areas formed by the sum of each of the dense plasma regions 3009 can be kept smaller relative to the surface area of the target material 3013 and the axial electrode 3001. This is advantageous for multiple reasons—the primary reason is to enable the plasma current density needed for local HiPIMS ionization, e.g. >0.3 A/cm2 while satisfying the maximum thermal properties to not melt or thermally shock the target material 3013. Or to allow a larger diameter radial magnetron for coating larger objects with a thermal budget or power budget. By using smaller individual magnetic-plasma regions 3022, the advantages of IMPULSE+Positive Kick HiPIMS can be achieved for many difficult to use materials or coating configurations—and preserving the spatial uniformity and target utilization benefits from target rotation or axial displacement.

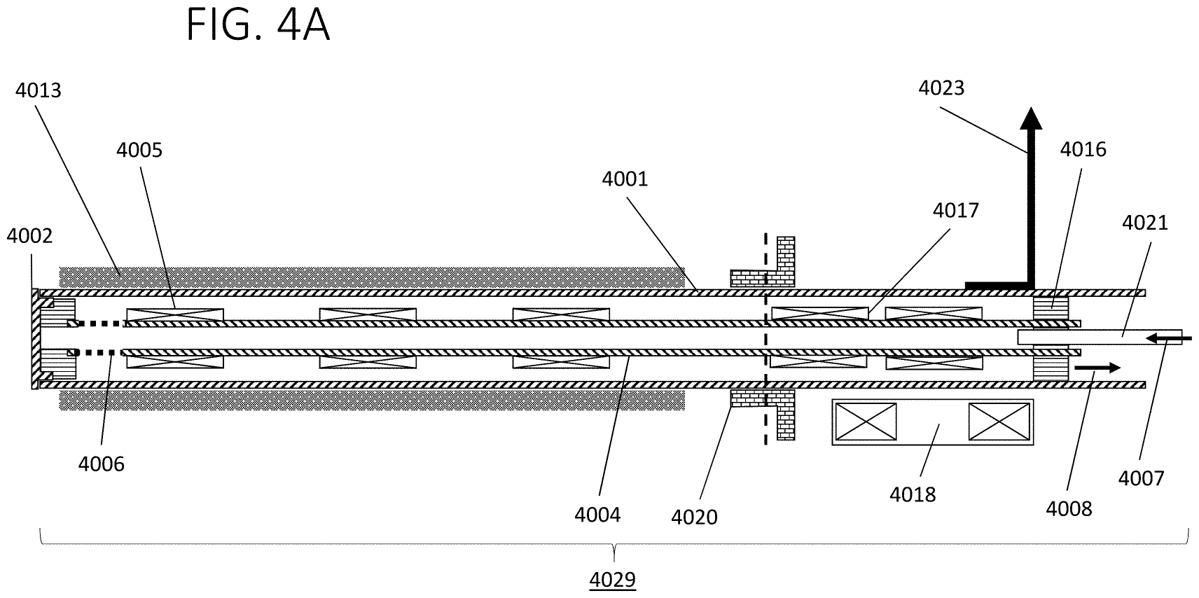

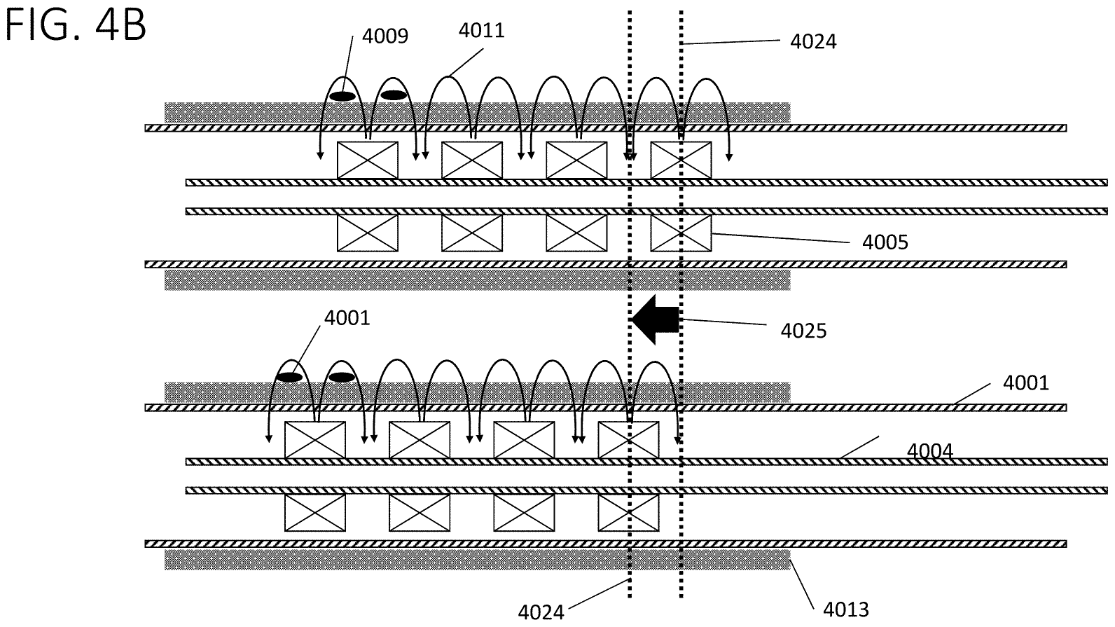

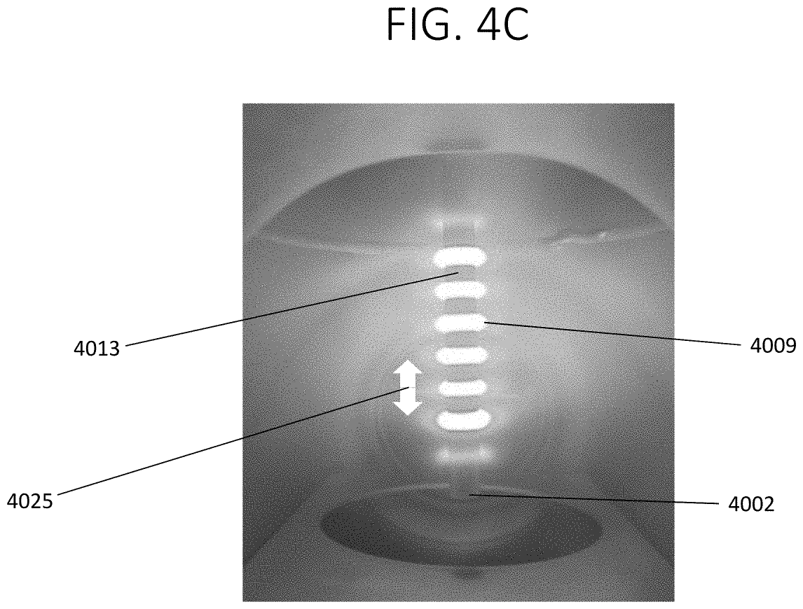

FIG. 4A schematically depicts a sectional view along the axis of a high-current radial magnetron system with the vacuum-side primary sputter/etch permanent magnet assembly capable of axial-displacement generating a moving target-region magnetic field coupled to an air-side external magnetic drive. The primary sputter/etch permanent magnet assembly 4005 is mounted to a magnet substrate 4004 that can serve as an interior coolant passageway from a cooling input tubing 4021 producing input flow 4007. The flow turn around is facilitated by a coolant transition or perforation 4006 to then pass over the axial electrode 4001 internal surface while passing through slotted bushings 4016 that maintain concentric orientation and allow movement of the primary sputter/etch permanent magnet assembly. A sputtering target material 4013 is affixed to the axial electrode 4001 and if the radial magnetron 4029 is an “end-type” confirmation, an end-cap 4002 closes off the unit. A high-current return line 4023 is attached to the axial electrode with hard contact and high-surface area for good electrical conductivity under pulsed operation for IMPULSE®+Positive Kick™ HiPIMS. A secondary internal motion permanent magnet assembly 4017 is mounted to the magnet substrate 4004 to provide magnetic coupling to the primary sputter/etch permanent magnet assembly 4005 via physical and/or magnetic connection. A secondary external motion permanent magnet assembly 4018 is placed external to the secondary internal motion permanent magnet assembly 4017 and isolated with insulating materials sufficient to protect against high-voltage conditions proximal to the high-current return line 4023. The secondary external motion permanent magnet assembly 4018 can be physically moved with external actuation (not shown) to move the magnetic assembly to achieve the desired motion on the primary sputter/etch permanent magnet assembly 4005. Again, the high-current return line 4023 provides robust pulse current capability.

FIG. 4B further depicts the axial displacement of the primary sputter/etch permanent magnet assembly in a radial magnetron configured for axial movement of the target-region magnetic field to generate dense plasma regions for sputtering and etching. The magnetic-plasma reference point 4024 over components of the primary sputter/etch permanent magnet assembly 4005 facilitates the target-region magnetic field 4011 that enables the formation of the dense plasma regions 4009 for sputtering and material transfer from the target material 4013 to the substrate (not shown). Axial-longitudinal magnetic-plasma displacement 4025 is accomplished by physically moving components of the primary sputter/etch permanent magnet assembly 4005 to shift the target-region magnetic field 4011 that moves the dense plasma regions 4009 for sputtering and material transfer from the target material 4013. The action of axial magnetic-plasma displacement 4025 serves to promote target uniformity, increased lifetime, stable process conditions and high-power operation.

FIG. 4C is a photograph of a high-current radial magnetron operating under IMPULSE®+Positive Kick™ employing a primary sputter/etch permanent magnet assembly capable of axial-displacement. Here is a 6.3-mm diameter end-capped radial magnetron 4002 with a primary sputter/etch permanent magnetic assembly arranged to create multiple dense plasma zones 4009 around the sputtering target electrode 4013 that can be axially translated 4025. This configuration is adapted to treat interior surfaces of structures having very small diameters and coating the interior of small tubes and difficult-to-reach locations. The radial magnetron has hard electrical contact with the pulse power module to sustain intense pulse current for HiPIMS and ionized PVD, as well as the Positive Kick features. While FIG. 4C demonstrates a very small diameter system, the radial magnetron can be scales to larger diameters for treatment of larger items with modification to the primary sputter/eth permanent magnet assembly.

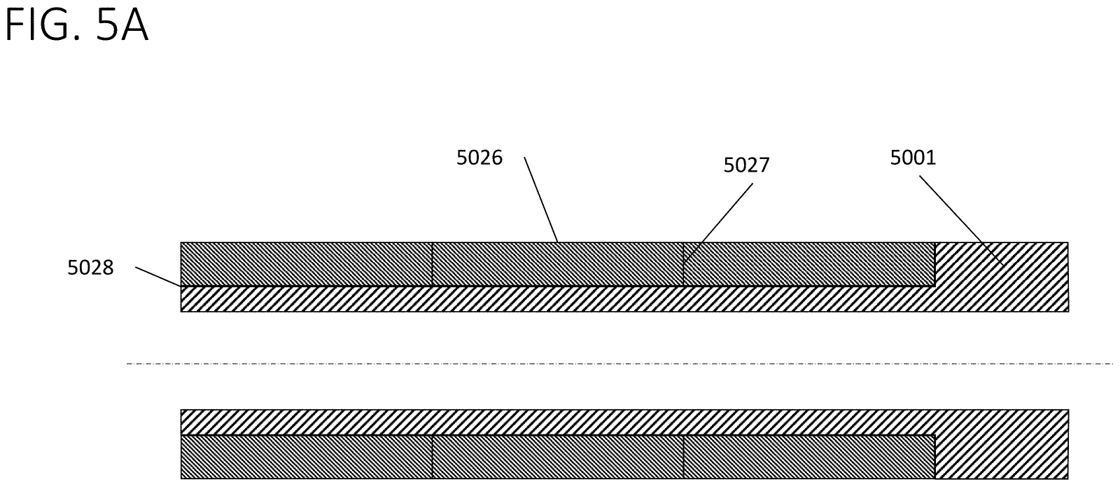

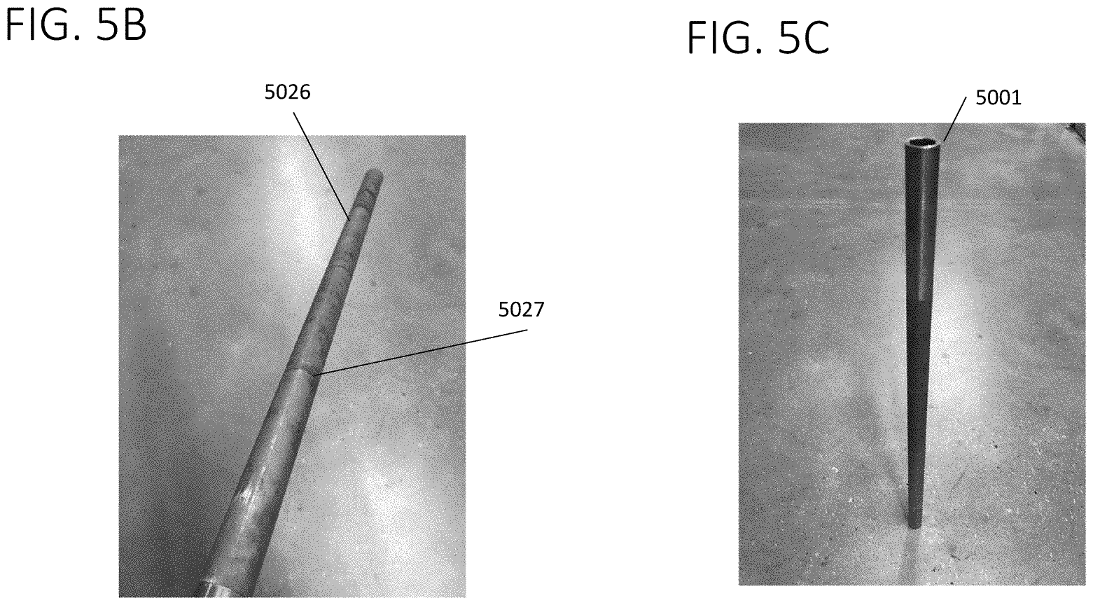

FIG. 5A is an illustrative example of the construction of a large radial magnetron axial cylindrical electrode with multiple externally-facing target material sections for the sputter/etch of a long substrate. Here the axial electrode 5001 material is bonded to target material 5013 with segmented target construction 5026. The individual segmented joints have a custom target overlap region 5027 to minimize seams and enable better uniformity for target operation and sputtering.

FIG. 5B is a photograph highlighting segmented niobium targets bonded to a copper axial electrode using a thermal shrink fit assembly technique. Here the axial electrode 5001 material can be a high-expansion, high-conductivity material, such as copper, and it is bonded to target material 5013, such as niobium, with segmented target construction 5026. The axial electrode is cooled in cold bath, e.g. liquid nitrogen, and then the segmented target construction 5026 is successively shrink-fit bonded on top. This yields a strong joint with excellent thermal contact for operation.

FIG. 5C is a photograph of a meter-long radial magnetron target-bonded electrode prior to assembly with internal magnetic assemblies and coolant flow structure. Alternate embodiments include using the axial electrode as the target material, using elastomer or indium bonding intermediaries, brazing, etc. Furthermore, conventional cylindrical rotary cathode construction using cold spray, atmospheric plasma spray, and other sintering/press techniques also work here.

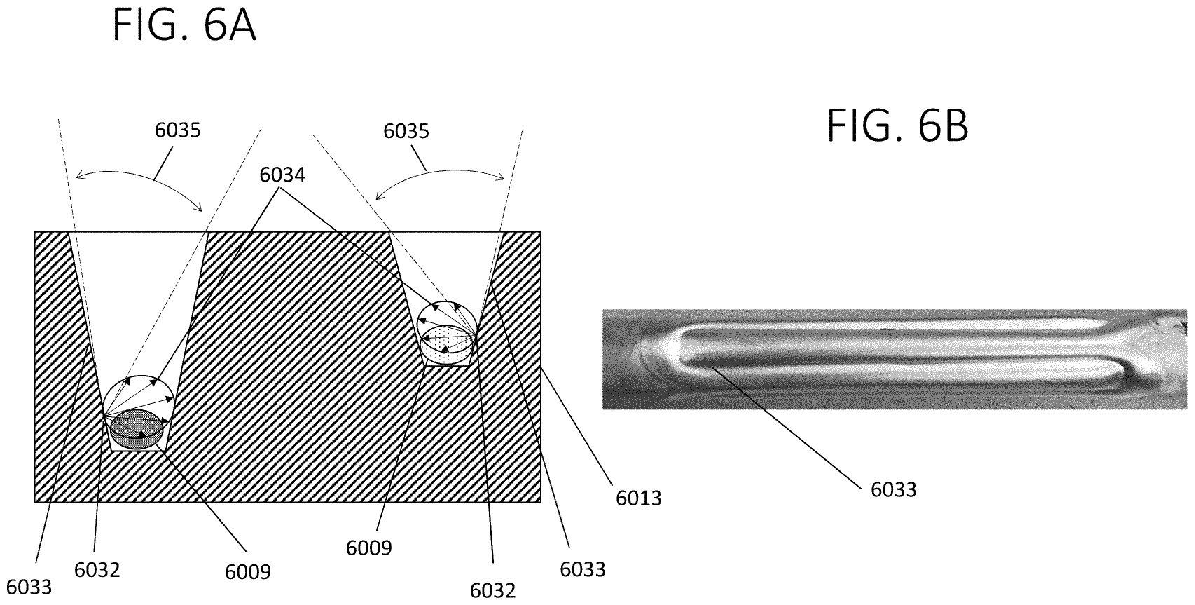

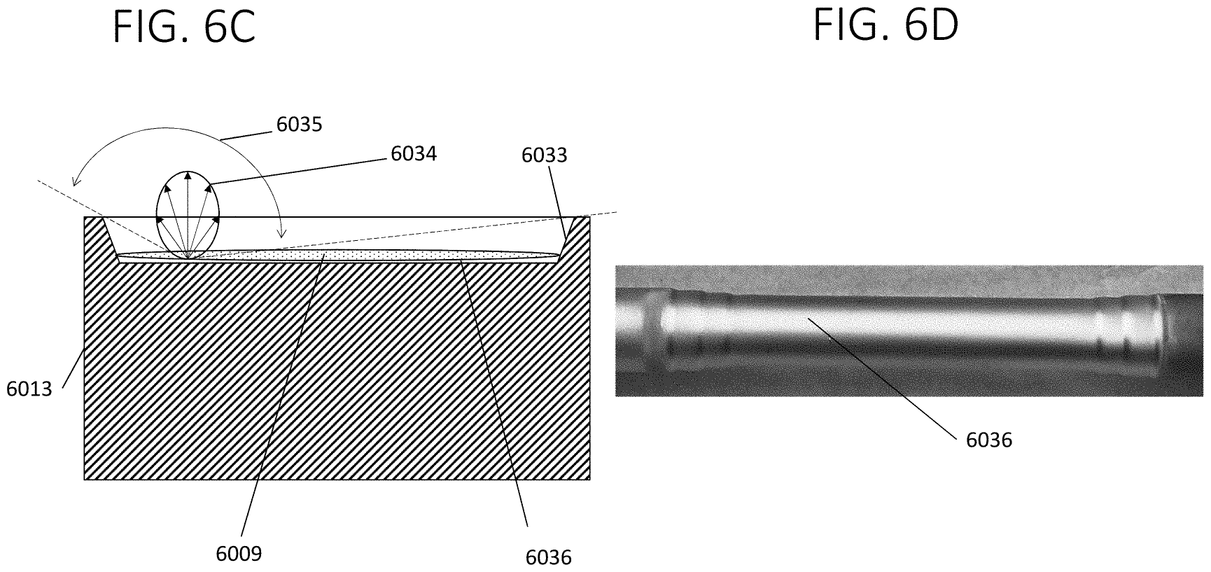

FIG. 6A illustratively depicts the formation of deep ‘V’ grooves from sputtering the target material surface without magnet-target rotation. The sputtering V groove 6033 is highlighted formed from the erosion of target material 6013 from dense plasma 6009 impingement on the sputtering region 6032 resulting in sputtering distribution 6034 only partially escaping through the sputtering V groove 6033 leading to sputtering emission angle 6035. This action over time limits the particle flux 6010 from reaching the substrate (not shown) to be coated. The magnetic flux density increases inside the target material 6013 closer to the primary sputter/etch permanent magnet assembly (not shown), promoting greater ionization and erosion causing deeper sputtering V groove 6033 leading to shorter target lifetime. The deeper sputtering V groove 6033 the less solid angle for material escape and a higher amount of material recycling occurs, lowering the overall deposition efficiency of the system. For multiple racetracks it is possible to have deeper racetrack grooves on some than others. This accelerates maintenance cycles.

FIG. 6B is a photograph of a radial magnetron after operation without magnet-target rotation showing the deep “racetrack” pattern of target erosion and non-uniformity.

FIG. 6C illustratively depicts a more uniform target material erosion pattern on the target surface resulting from magnet-target rotation (relative movement between the dense plasma regions and sputter target material) and the minimization of sputter V groove 6033 to the axial target edges for better utilization and process uniformity. Note the sputtering emission angle 6035 is significantly greater with near-normal sputter distribution 6034. Not only does this results in vastly improved target utilization, but since the erosion does not wear an ever-deepening groove into the target, the plasma operating conditions are much more stable as the target ages.

FIG. 6D is a photograph of a radial magnetron after operation with magnet-target rotation showing target uniform erosion profile 6036, elimination of deep ‘V’ grooves, and increased target utilization. Comparing FIG. 6B and FIG. 6D shows the relative difference in erosion patterns and utility of the present invention. With rotation or axial adjustment of magnetic field relative to the target, improved uniformity and sputter V groove 6033 can be achieved for greater solid angle emission and target utilization.

FIG. 7A is a photograph of the prior art showing copper electroplating including discolorations due to embedded defects and impurities from the plating solution on a stainless-steel hydroformed vacuum bellows for cryogenic particle accelerator applications. FIG. 7A is an example of a bellows structure having a surface treated/formed using a prior art approach for electroplating stainless-steel cryogenic bellows for RF accelerators. In the image provided in FIG. 7A, the variable quality of the copper plating may be observed with an inability to deposit plate material on the sidewalls of the vacuum bellows section due to masking and nickel strike layer difficulties. Prior art method may be replaced, with beneficial results of better surface treating/plating by use of the deposition/sputtering operations of the present disclosure.

FIG. 7B is from the prior art depicting regions in a large-scale superconducting RF particle accelerator cryogenic module where high-purity PVD coatings could be utilized, i.e. long spool, short bellows, long bellows, beamline sections, SRF elliptical cavities, etc. FIG. 7B illustratively depicts a prior art arrangement for a superconducting RF accelerator section comprising multiple spools, bellows and RF cavities needing specific material properties. The present disclosure addresses multiple sections with wide application.

The radial magnetron disclosed herein enables conformal coatings on accelerator surfaces, including RF cavities, RF seals, bellows, and actual vane tips, I-H structures, dielectric loading structures, tuning elements and electrodes. Adjusting the IMPULSE®+Positive Kick™ properties for a given radial magnetron configuration can adjust material properties around the Thornton/Anders Structure Zone Diagram with different electrical, thermal, grain structure, mechanical and stoichiometry/composition. For accelerator needs, properties such as secondary electron emission, smooth and high-field emission limit materials can be deposited and well adhered in high stress locations, whereas high-conductivity bulk material can be coated in areas where low resistance is needed. For spools, straight beamline sections and bellows, superior copper with high RRR can be achieved. Similarly for SRF cavities, a preferred-orientation Cu base layer can be deposited with a thin insulating NbN layer with the main Nb coating layer on top to optimize superconducting properties. Other combinations, materials, composite structures and locations are possible with the radial magnetron. For linear electron beam cavities, leading edge disk apertures are coated with one type of coating for the high field region and the cavity zones are coated with a different type of film structure. For example, ultra-smooth, nano-crystalline or amorphous high-gradient materials on the vane tips and preferred orientation high-conductivity copper in the cavity zones.

FIG. 7C is from the prior art showing RF power loss and thermal dissipation due to poor electrical conductivity with electroplated copper showing the temperature increase in a cryogenically-cooled vacuum bellows section for two different RRR values vs. coating thickness highlighting the need for high-purity thin-film coatings. FIG. 7C illustratively depicts performance properties of a prior art showing RF power loss and thermal dissipation due to poor electrical conductivity with electroplated copper. The thickness of the film determines both magnitude of RF losses and ability of the structure to conduct that deposited thermal energy outward. This is important for not only accelerator cavities but also bellows sections, transfer tubes and other beam structures. Trapped RF modes are a source of heating that exist in accelerator structures such as bellows. For superconducting accelerator cryomodules that are kept at liquid He temperatures, any thermal energy deposited here will be removed solely via conduction along the bellows surface to its edges. To minimize heating, as close to pure (e.g. high RRR) copper films having a thickness of >10 μm is highly desirable for these applications. Starfire's IMPULSE®+Positive Kick™ technology addresses this by enabling stress control in the deposited films. This allows the process engineer to deposit films having little to no internal stress, which is critical for thick, large-area films.

FIG. 7D is a prior art-related photograph of a structure including embedded defects and impurities from an electroplating copper solution and the impact on a stainless-steel bellows. A surface treated according to the prior art showing surface defects, corrosion, trapped material, inclusions and surface asperities in conventional copper electroplating leading to poor accelerator performance. The IMPULSE®+Positive Kick™ and Super Kick™ modes controls net deposition, etching, or doing both for smoothing/roughness-fill. Releveling a surface is beneficial to high-gradient (i.e. spark-resistant or spark-tolerant) accelerator films. The initial spark resistance results in smoothness, but that the overall tolerance comes more from a lack of inclusions that are provided by depositing a controlled film in an atom-by-atom process vs. bulk casting and machining. After a first arc, the local surface is no longer smooth. Therefore, the film impurities/defects/inclusions determine performance of a treated surface.

FIG. 7E is a prior art summary of defect materials and sizing in typical electroplated copper used in particle accelerator applications that have some contribution to the lower RRR, surface defects that can lead to sparking and electron emission under high electric fields, and poor performance. FIG. 7E is an illustrative summary of performance of surfaces treated according to the prior art. The summary shows the presence of inclusions in electroplated copper by size and material impurity. The surface treatment and formation operations and structures described herein according to the present disclosure enable controlled deposition of materials on an atom-by-atom basis, greatly limiting inclusion size and composition to suppress local field enhancements and multipactoring and sparking.

The proposed illustrative examples using conformal ionized physical vapor deposition replaces wet chemical electroplating (e.g. Cu) for stainless-steel bellows and specialty vacuum components used on accelerator structures. Wet chemical electroplating is being progressively phased out due to its damaging environmental impact, hazardous chemical handling, high cost, and lack of experienced tradespeople in the field. In the EU there are proposals and timelines for the complete phase out of all electroplating in the coming years, making investment in alternative technologies important. There are known issues with surface finish/roughness (including macroscopically visible striations in the plating), inclusions, particulates from both the copper plating itself, as well as those potentially introduced during the electroplating or subsequent surface smoothing steps (e.g. Mo-wool polishing or bead blasting).

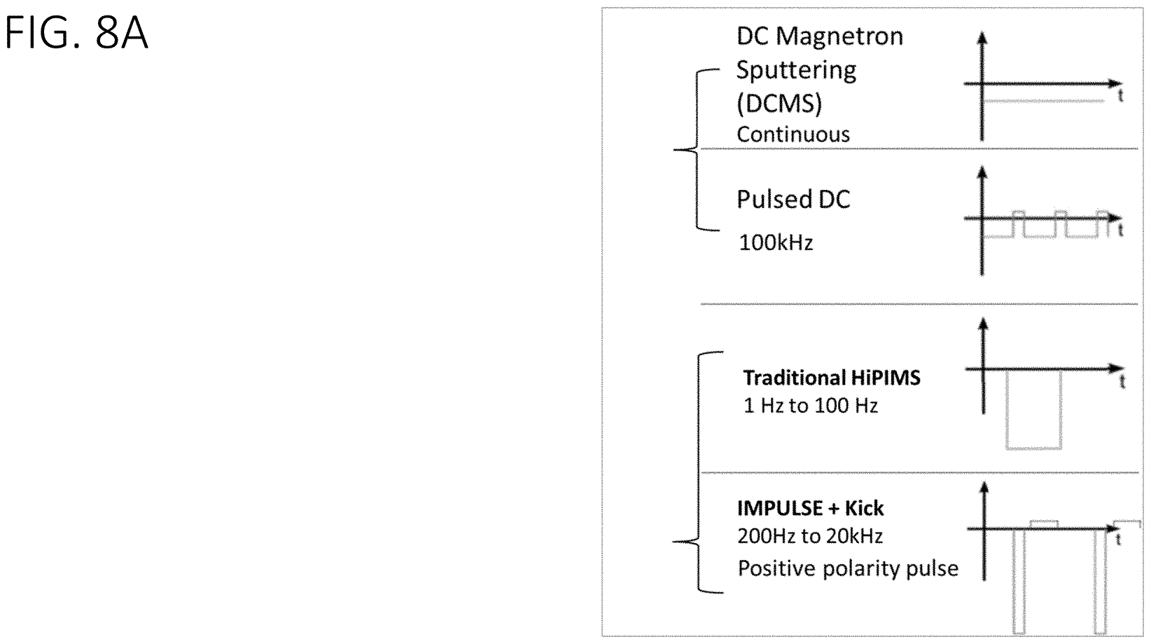

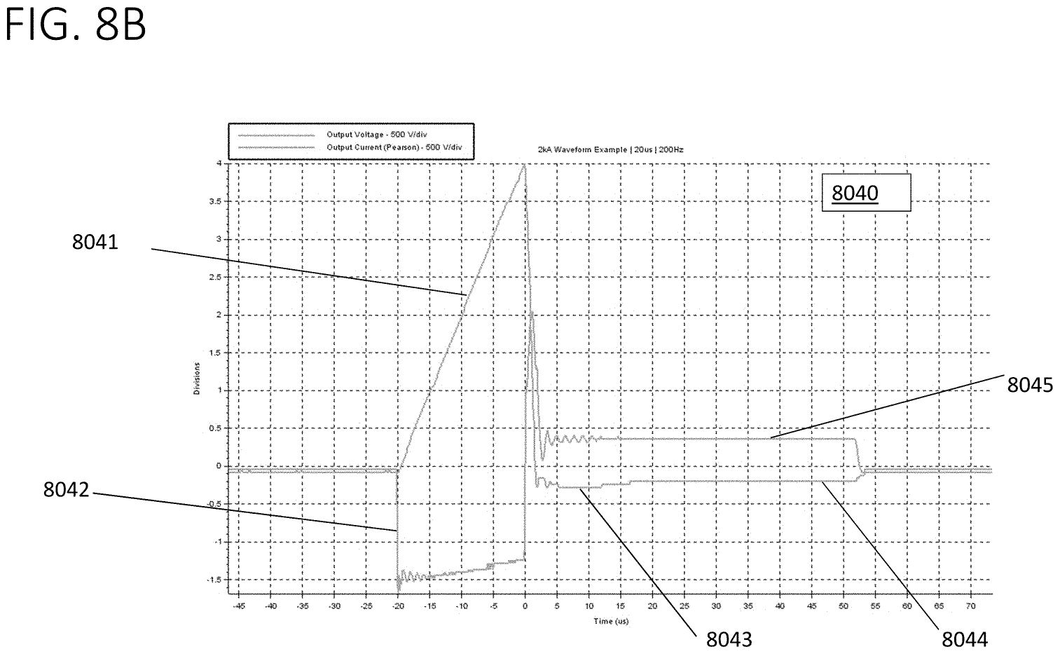

FIG. 8A illustratively depicts a comparison of traditional DC magnetron sputtering (low current, low ionization), pulsed DC (lower current, low ionization but better for reactive gases), traditional HiPIMS (high current, high ionization but low deposition rates), and IMPULSE®+Positive Kick™ (high current, higher ionization rates and higher deposition rates). Typically, HiPIMS plasma current densities are ˜0.3 A/cm². Using an ultra-fast impulse followed by a Positive Kick pulse can exceed 3 A/cm² with good film properties and is used as a factor in designing the inverted magnetron structure for high peak powers for more intense ionization, conformal plasma etching and deposition.

FIG. 8B is an illustrative pulse waveform 8040 highlighting the specific features of the IMPULSE®+Positive Kick™, specifically the intense, high main pulse current 8041, main pulse negative voltage 8042 region generating significant target sputtering and ionization of target material, the Positive Kick™ voltage 8045 reversal that expels plasma from the target-region magnetic field in the form of energetic ions (short kick 8043) and bulk plasma transport to the substrate (long kick 8044)—the oscilloscope waveform is a Cu plasma achieving 2 kA peak current in 20 microseconds with subsequent +200V positive pulse for 50 microseconds. The ultra-fast IMPULSE® technology can routinely push current densities >10 A/cm2 (which is more than 10× standard HiPIMS) leading to >90% ionization rates for directed iPVD. Extreme high current magnitudes require hard electrical contact with physical area for pulsed current propagation. The radial magnetron has a fixed axial electrode with high surface area for hard metal contacts that can handle IMPULSE pulsed currents. The radial magnetron in FIG. 2A and FIG. 4A show the hard, high current contact 4023 that is enabling. Additionally, particle generation is further minimized by the fact that none of the vacuum facing surfaces/components move; only the radial magnetron internal magnet assembly, which does not see vacuum, is rotating or moving.

With continued reference to FIG. 8B, additional detail is provided on the oscilloscope waveform 8040, including a Cu sputtering plasma achieving 2 kA peak current in 20 microseconds during the Ultra-Fast HiPIMS phase with subsequent +200V positive pulse showing Short and Long Kick phases. The voltage waveform 8042 and a current waveform 8041 for a −750V, 2 kA peak current HiPIMS pulse achieving a plasma current density of 5 A/cm2 on the cylindrical magnetron with a copper sputtering target with a positive kick pulse of +200V, 125 A peak current highlighting a short kick 8043 and a long kick 8044. The IMPULSE® technology described herein drives plasma generation at high dI/dt to achieve rapid ionization for subsequent voltage reversal and Positive Kick™ to accelerate ions and plasma into substrates for superior cleaning, etching, preferred-orientation deposition and deposition with stress and morphology control. The technology also allows for synchronization with pulsed DC bias supplies for time windowed acceleration into the substrate for additional control as taught in US20180358213A1.

Depending on local factors such as pre-ionization, target material, magnetic field, pressure, geometric curvature, sputtering gas, surface chemistry, adsorbed gases, etc., the main negative pulses on the voltage waveform 8042 are typically in the range of −400V to −1200V. Using the ultra-fast switching topology typical high-current pulse widths are less than 100 usec, with a typical range of 20-50 usec. The Positive Kick™ amplitude on the voltage waveform 8045 are typically in the range of +0-600V. For users who do not want the short kick ion population group to be accelerated away from the sputter target, shown in the current waveform for the short kick 8043, the onset delay in the positive kick would be set to after this time period typically set at 20-40 usec. The ionization rate and plasma density near the sputtering target is highly coupled with the effective current density. Effective current densities are typically in the range of 0.1-10 A/cm² depending on materials.

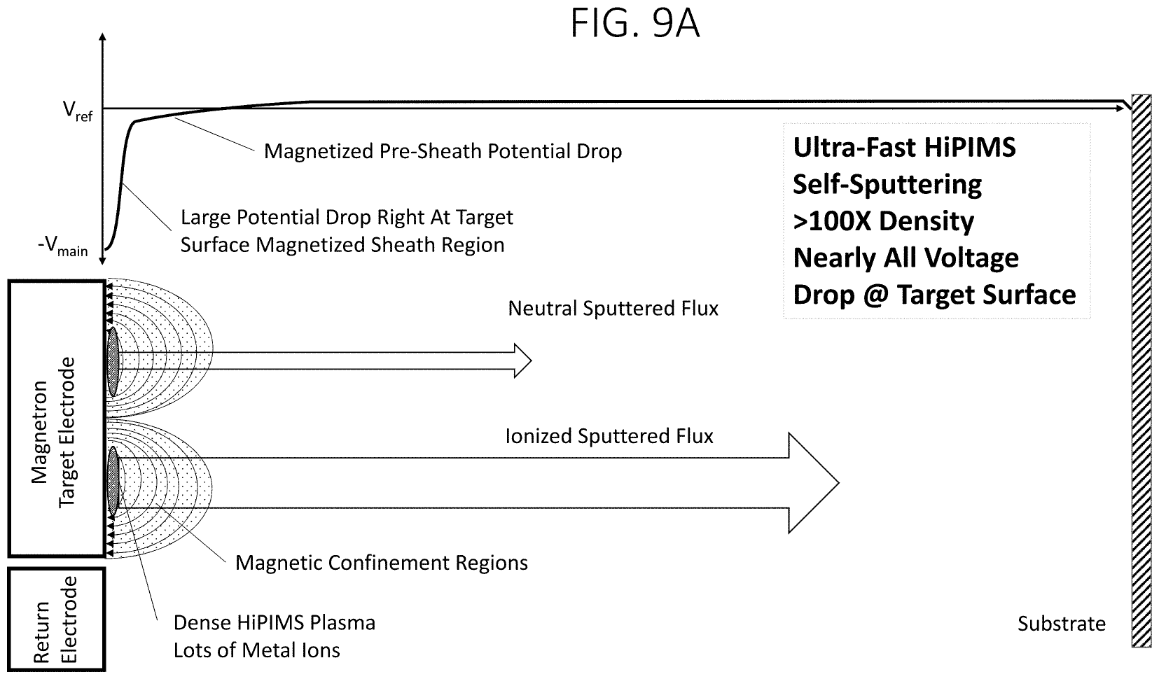

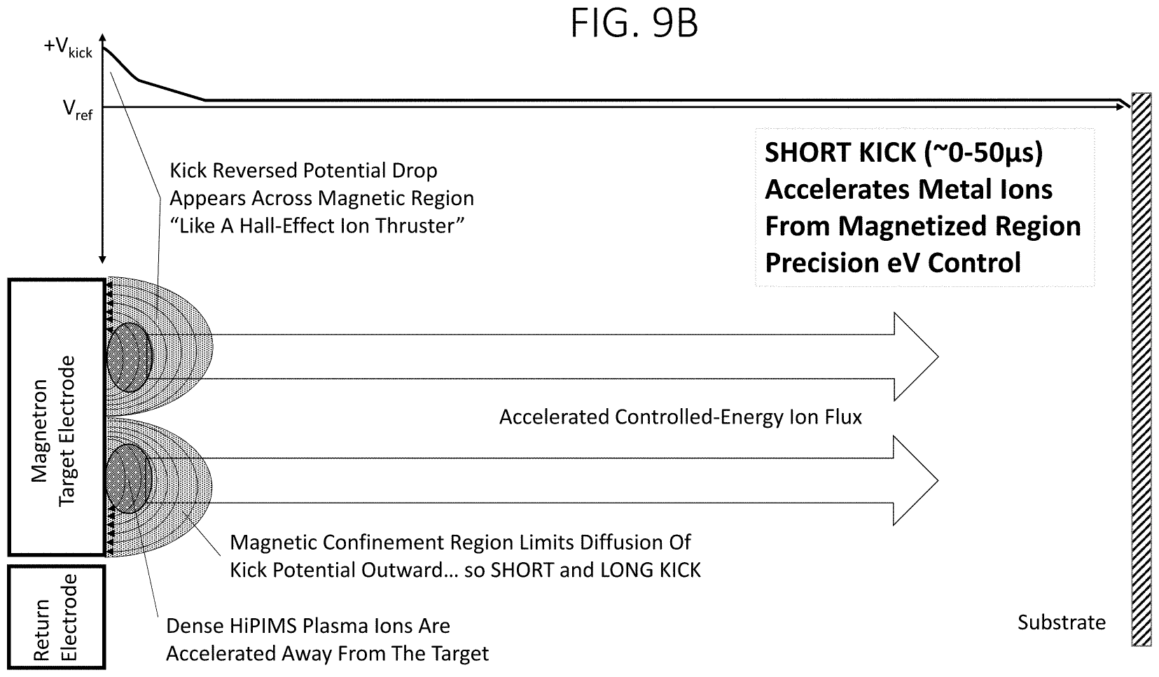

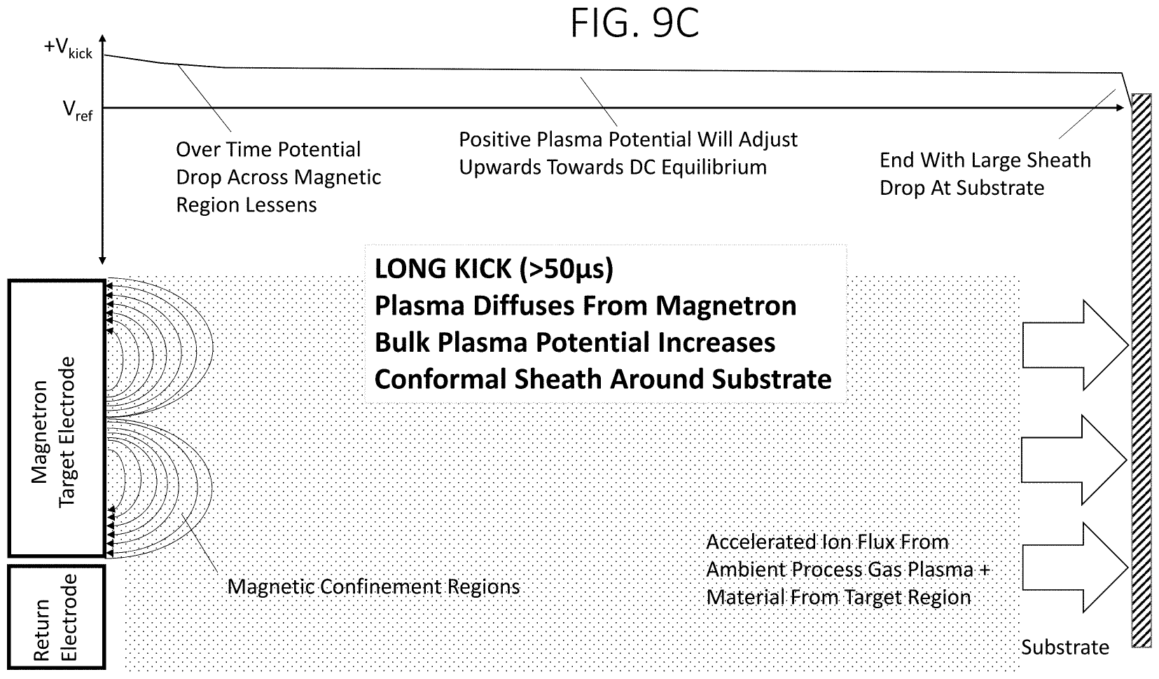

An aspect of the disclosure provided herein is the ability to control, during operation of the apparatus described herein, the flux and energy of ions deposited/impacted onto substrates for the preparation and deposition of thin-films with engineered properties. FIG. 9A depicts an illustration of the 1^{st} of 3 phases during an IMPULSE pulse operation—the Ultra-Fast HiPIMS phase. FIG. 9A is adapted from US Application Publication US20180358213A1 and illustratively depicts an ultra-fast high-power impulse magnetron sputtering and the potential distribution between the sputter target and the substrate.

FIG. 9B depicts an illustration of the 2^{nd} of 3 phases during IMPULSE® operation—the Short Kick phase. FIG. 9B is adapted from US20180358213A1 and illustratively depicts an ultra-fast switching and positive voltage reversal on the target electrode to a positive voltage and the evolution of the potential distribution across the magnetic confinement region near the target electrode—the Short Kick accelerating ions from the dense HiPIMS plasma region away from the target electrode typically perpendicular to magnetic field lines.

FIG. 9C depicts an illustration of the 3rd of 3 phases during IMPULSE® operation the Long Kick phase. FIG. 9C is adapted from US20180358213A1 and illustratively depicts a positive potential evolution into the Long Kick phase where the plasma potential of the bulk is increased, and conformal sheaths form on the substrate and other surfaces where the bulk plasma is commuted.

A high level of customization afforded with the combination of ultra-fast high-current pulsing with rapid positive voltage reversal with the cylindrical magnetron configuration enables superior and novel films, including advanced nanolayer composites and functionally-graded materials with specific attributes, including high-electrical gradient standoff, high-voltage tolerance, high-electrical conductivity, ultra-smooth surfaces, oxidation resistance, thermal fracture toughness, crack arresting features, diffusion barriers and anti-wear, anti-corrosion, ductile vs. stiffness, lubricious properties, etc. Specifically, the deposition of superconductor-insulator-superconductor layers with low bulk temperature highly sought after by superconducting wire, magnetic tape, RF cavity and accelerator engineers.

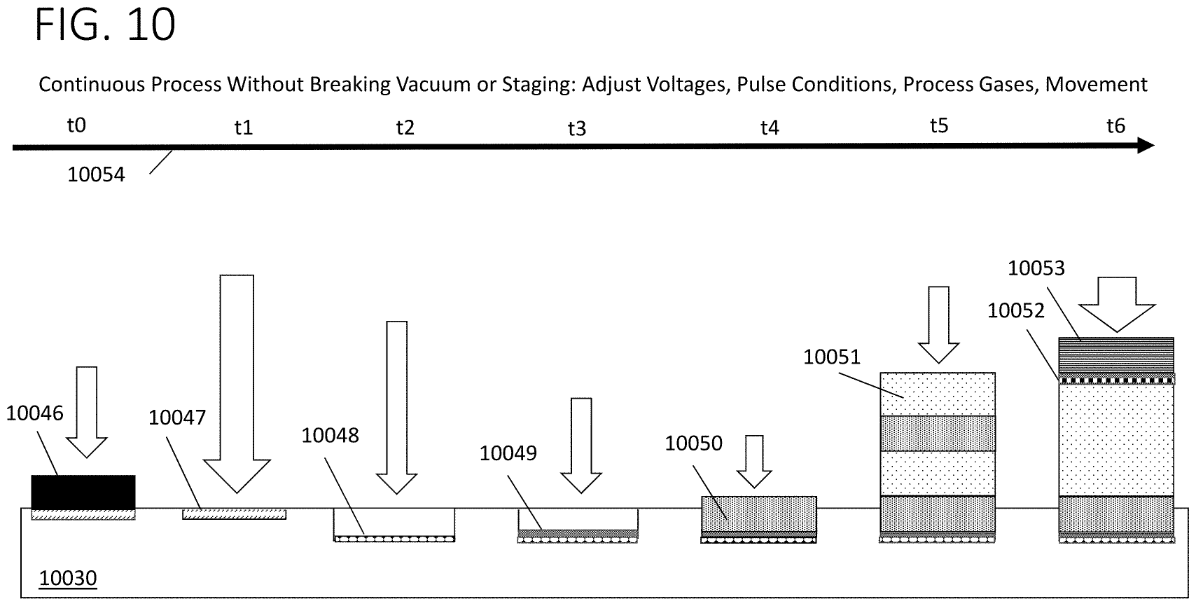

FIG. 10 depicts an illustration of a continuous process adjusting IMPULSE parameters 10054 using the IMPULSE®+Positive Kick™ without breaking vacuum, interruptions or staging. This is important in terms of substrate 10030 interface quality and cleanliness. One monolayer of atoms will roughly cover a surface in 1 second at a base pressure of 2e-6 Torr (a typical base pressure for high vacuum systems). The ability to transition from cleaning to etching to implantation to bulk deposition with minimal pause greatly improves the fidelity of the coatings and surface modification. The central advantage in terms of combining cleaning 10046, etching 10047, ion implantation 10048, adhesion control 10049, stress management 10050, bulk material deposition 10051, diffusion barriers or insulating layers 10052, and reactive/capping layer 10053 depositions. With precision ion energy control, the ultra-fast IMPULSE® with positive voltage reversal can remove surface contaminants, etch near-surface damage, develop a mixing interface for a good adhesion layer, to support stress-controlled layer(s)s that enables bulk films to be grown with suitable interface and capping layer(s).

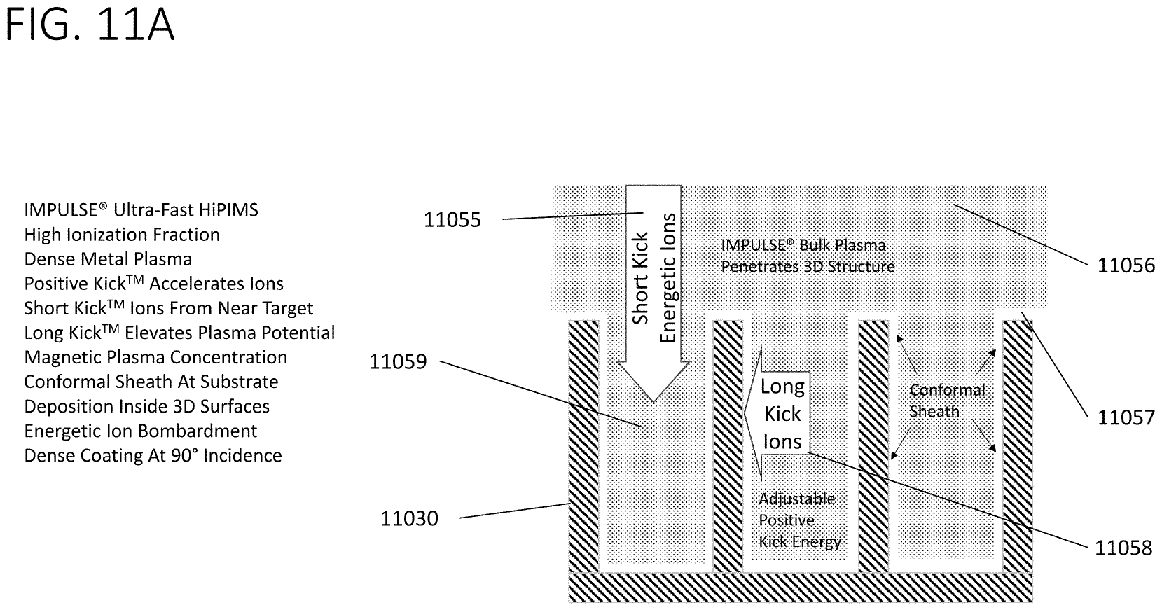

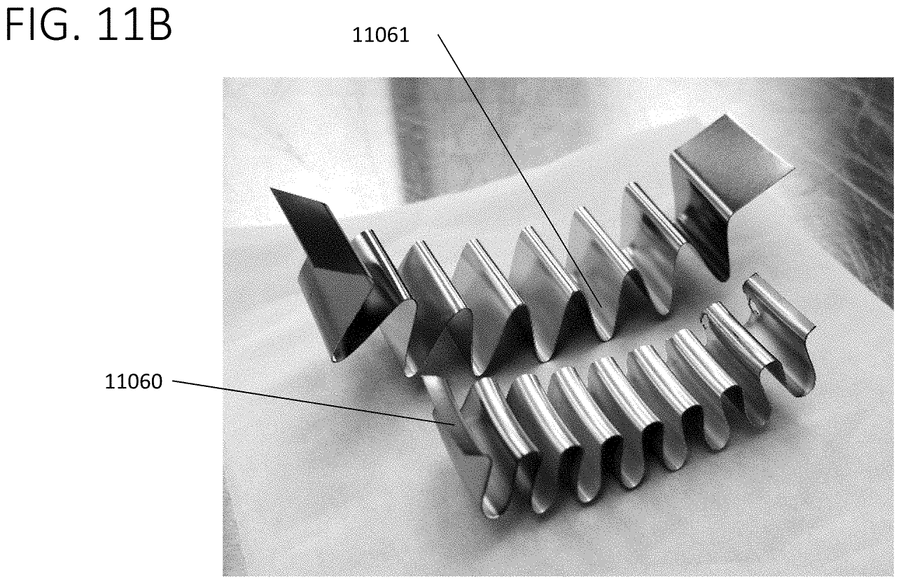

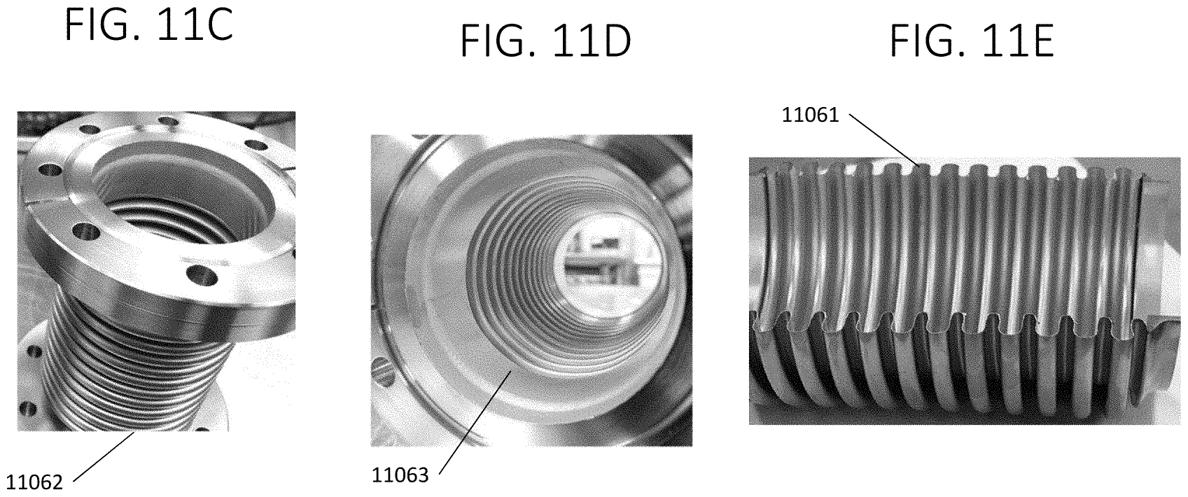

FIG. 11A. is an illustration depicting the effects of the IMPULSE®+Positive Kick™ at a substrate that exhibits 3D or high-aspect features, including energetic ion bombardment from the short kick phase, substrate immersion in bulk plasma expansion with subsequent quasi-conformality and ion bombardment from the long kick phase. Using radial magnetron configurations discussed herein, the IMPULSE® ultra-fast high-power impulse magnetron sputtering (HiPIMS) technique can be used to generate a dense metal plasma and an ultra-fast voltage reversal for carrying out Positive Kick™ and Super Kick™ techniques to accelerate ions and plasma to the substrate for modification. FIG. 11A depicts an illustration of an example of using the IMPULSE®+Positive Kick™ for conformal coating of substrates. During HiPIMS pulses the electrical current can be 10-1000× higher than conventional DC sputtering. Combined with ultra-fast IMPULSE® pulsing technology, peak power densities can be achieved <<100 usec leading to very high plasma densities. The Positive Kick™ voltage reversal and positive bias pushes ions and plasma away from the dense magnetic field regions on the magnetron to increase the local plasma density near the substrate during the pulse. This high-density bulk plasma expansion from the Positive Kick 11056 will have a short Debye length allowing 3D structure plasma penetration 11059 to the substrate 11030. Applying the Positive Kick initially accelerates ions from the magnetic confinement zones with directed energy 11055 following Grad B and eventually float bulk plasma potential up such that a conformal sheath 11057 will appear around the substrate 11030 and accelerate additional ions 11058 to the substrate. If the features are larger than several Debye lengths, then conformal deposition will result. An additional result of the Positive Kick is an increase in ion capture efficiency which is important from an economics perspective.

FIG. 11B is a photograph of high-aspect ratio stainless-steel bellows sections in a traditional W and Ω shape treated with a Radial Magnetron™ +IMPULSE®+Positive Kick™ demonstrating quasi-conformal Cu coverage, having high strength and surviving cryogenic immersion, heat treatment, plastic deformation stretching, and cyclic fatigue without buckling, delamination or film failure to replace conventional electroplating and wet electrochemistry for stainless steel cryogenic accelerator bellows. In the foreground, the bellows structure coupon 11060 to be coated is made from hydroformed stainless steel suitable for cryogenic applications. The as-received material is inserted into the cylindrical magneton system and IMPULSE® applied with Positive Kick™ for adhesion and surface adatom mobility and Super Kick™ for etching/cleaning. The continuous thin/thick film is conformal deep into the high-aspect ratio features 11061 forming the bellows expansion channels. The adhesion and film quality are enough to survive a 400° C. air bake and immediate immersion into LN₂ without spallation, delamination, or material failure. The material is cycled through >1000 full-range expand-compress strokes without failure of the film.

FIG. 11C is a photograph of a stainless steel hydroformed bellows section 11062 coated on the inner diameter with an insertable Radial Magnetron using IMPULSE®+Positive Kick™ HiPIMS etching and deposition. FIG. 11D is another photograph down the inner bore 11063 of the same bellows from FIG. 11A highlighting the uniformity of coverage. FIG. 11E is a photograph of a wire-EDM destructive test to cross-section the copper coating showing continuous coverage and no material failures. The radial magnetron+IMPULSE®+Positive Kick™ reliability demonstrates the ability to perform an in-situ clean/etch and shallow implantation to achieve superior adhesion and of the film. The wire EDM cross section 11061 was needed to examine the film properties and cross-section because it could not be separated from the stainless-steel substrate without destruction of the part.

The present disclosure allows very thick, stress-controlled, fully-dense, high-conductivity, well adhered coatings to address the bellows and SRF challenge. Low-temperature deposition using the Positive Kick and IMPUSLE allows a higher effective T* and E* to get the right orientation without high bulk temperature that results in interdiffusion of the layers. Added knob of kick voltage/duration is meaningful. Changes T* on the Thornton zone diagram without requiring direct heating of the substrate. Low actual substrate temp prevents diffusion in nanolayered materials (e.g. SIS structures). Adjustable surface mobility good for low defects are critical for SC films.

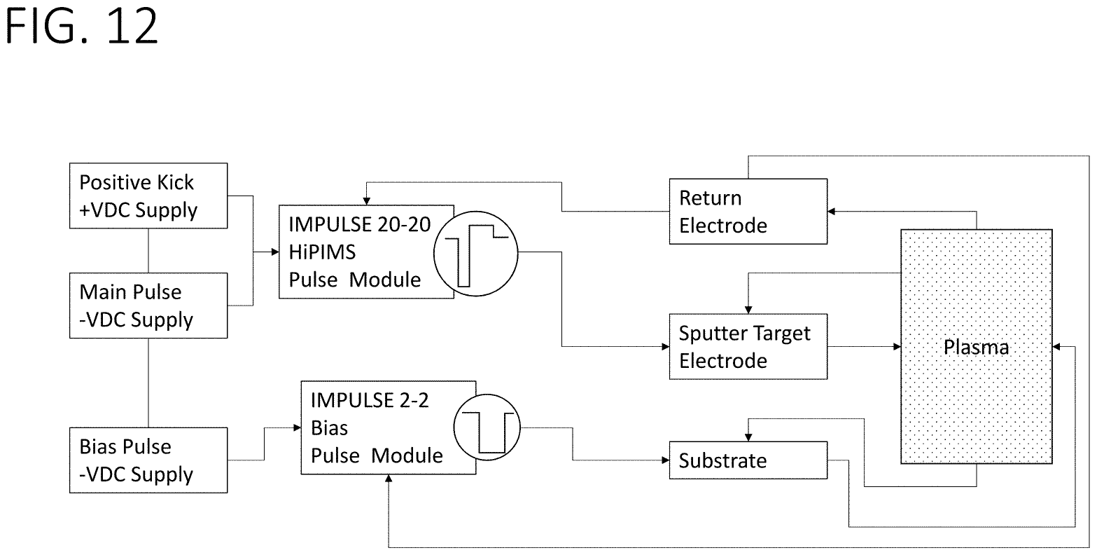

FIG. 12 depicts a high-level schematic representation of the thin-film deposition, etch and surface modification system with IMPULSE® pulse modules and power supplies. FIG. 12 is a schematic a block diagram showing an illustrative example of an electrical component/circuitry arrangement between a sputter target electrode, a return electrode, a substrate, a plasma in a vacuum environment and one or more IMPULSE® HiPIMS pulse module(s) (its main and kick supplies) and any IMPULSE® bias pulse module supplies. The schematic block diagram in FIG. 12 outlines a generic setup of IMPULSE° systems for deposition and etching. High voltage electrical pulses are provided from the external pulsed power modules directly to the sputter target through appropriate insulation and low-impedance connections. By rotating the magnetic assemblies, this allows for low-impedance electrical connections to the sputter target holder for efficient power transfer and coupling. The IMPULSE° modules are designed for parallel synchronous and asynchronous operation. Therefore, multiple units can pulse in parallel to delivery needed power, risetime and plasma density for a sputtering target electrode configuration.

A typical radial magnetron system setup is shown next. FIG. 13A is a photograph of an IMPULSE® pulse module and related power supplies. FIG. 13B is a schematic illustration of a single radial magnetron in-line deposition system 13064 for the surface modification, etch and deposition of vacuum bellows and accelerator components using the IMPULSE®. FIG. 13C is a schematic illustration of a multiple radial magnetron in-line deposition system 13065 for the surface modification, etch and deposition of an example Cu cavity for a superconducting coating comprised of more than one material, e.g. radial magnetron A and radial magnetron B. The schematic mirrors FIG. 12 with additional detail specific for the type of radial magnetron setup (single, multiple, end-cap, straight through, etc.). For FIG. 13C, specifically with multiple radial magnetrons, one radial magnetron can be used primarily for the initial substrate cleaning and etching step to collect the etch/removed materials. Additional means for removal of impurities that are non-volatile are to bury them into the chamber wall, into a sacrificial anode or other electrode, or have the impurities fall onto the non-active area of the etching radial magnetron and be buried during the deposition step. An example configuration highlighted in FIG. 13C, a copper radial magnetron can deposit a clean, pure interface layer onto the substrate to create known electrical, physical, and morphological properties (such as a preferred Cu orientation to grow the Nb on), and then the second radial magnetron can deposit niobium for superconducting properties or a nitride layer, such as NbN, etc. This is illustrating the coating of an SRF cavity.

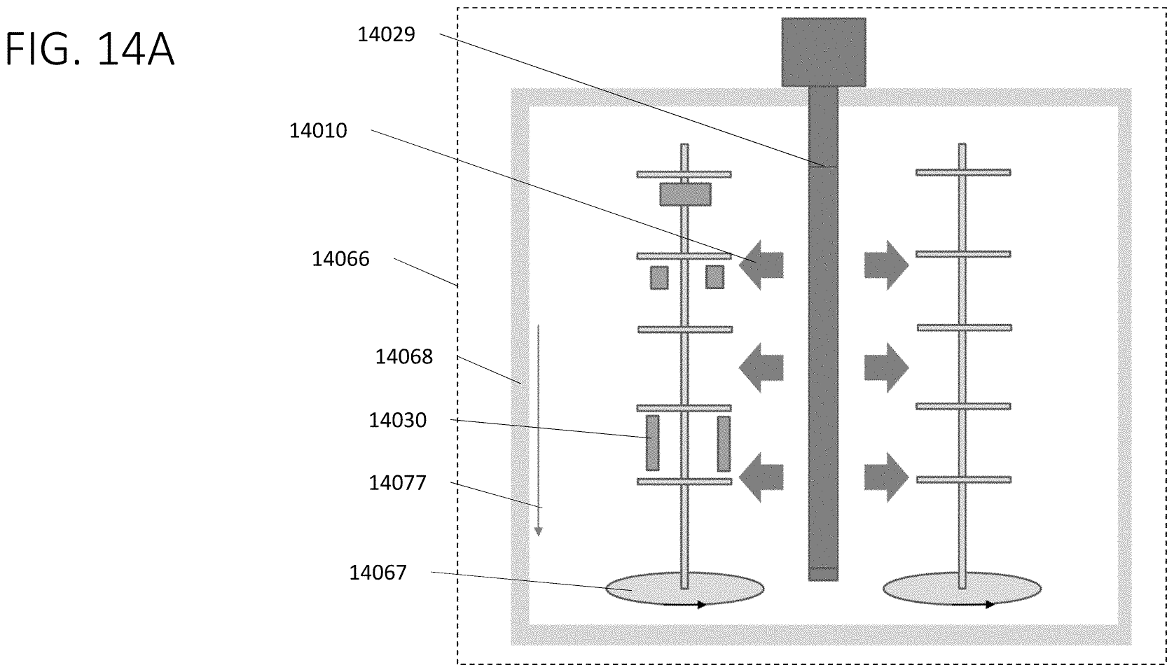

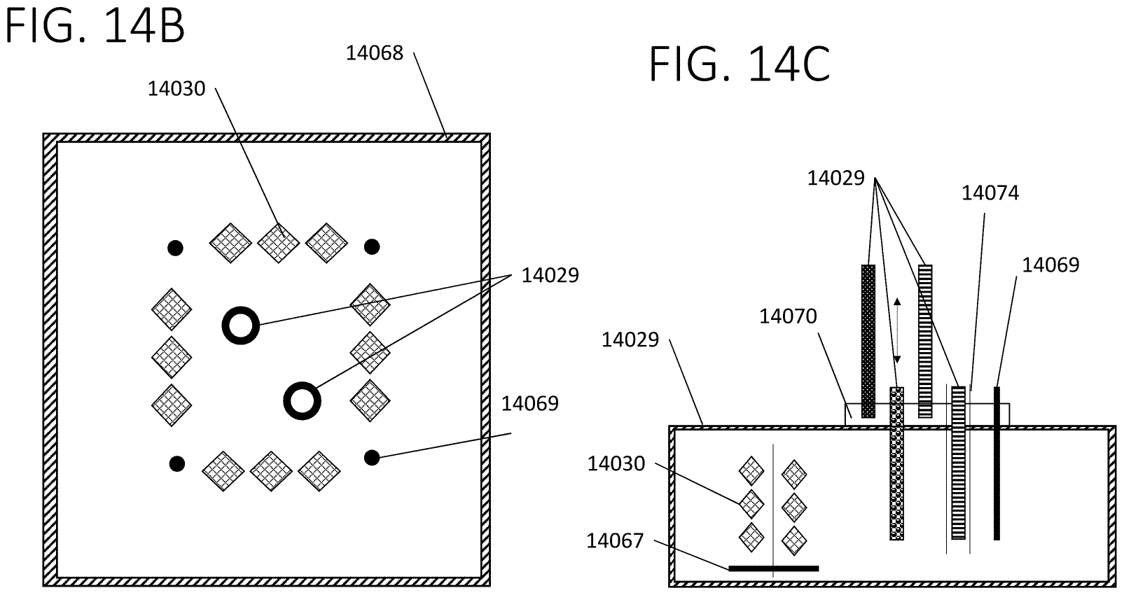

Broadening processing beyond simple in-line systems for cavity, bellows or tubing/pipe coatings, the radial magnetron can be extended for batch coating applications. FIG. 14A illustrates a side-profile schematic illustration of a radial magnetron batch deposition system 14066 comprising a vacuum chamber 14068, at least one radial magnetron 14029, and at least one substrate mounting structure 14067 interposed between the radial magnetron and the vacuum chamber wherein substrates 14030 are etched or deposited with plasma and material generated 14010 at or near the radial magnetron 14029. A major benefit of the radial magnetron batch deposition system 14066, is that target material source(s) can be interspersed within substrates 14030 and mounting structures 14067 to get greater target utilization, and vacuum chamber walls 14068 can be located further away from mounting structures 14067 and substrates 14030 such that particular debris 14077, formed after repeated deposition and venting cycles on the batch coater can be minimized. This is an additional benefit compared to traditional batch coaters employing planar magnetrons and rotary cylindrical magnetrons on the vessel exterior walls. Substrates are often located close to walls where particulate debris 14077 can build up.

FIG. 14B is a schematic illustration of a radial magnetron batch deposition system 14066 highlighting placement of one or more radial magnetrons 14029, multiple substrate mounting structures 14067, auxiliary anodes 14069, and the vacuum chamber boundary 14068.

FIG. 14C is a side-profile schematic illustration of a radial magnetron batch deposition system 14066 highlighting an exchange system 14070 for insertion/extraction of multiple radial magnetrons 14029, shield covers 14074, and auxiliary anodes 14069. The shield covers 14074 can serve two proposes to protect one magnetron target material while in the presence of another, as well as serve for anode current return in the ambient plasma or potential biasing. The radial magnetron batch deposition system 14066 offers potential for large-volume batch processing for multiplexed substrate mounting structures 14067 to handle large substrate 14030 volumes. In combination with the IMPULSE® +Positive Kick™, the bulk plasma generation from multiple radial magnetrons operating in coordination can lead to enhanced plasma immersion for near conformal deposition and etching.

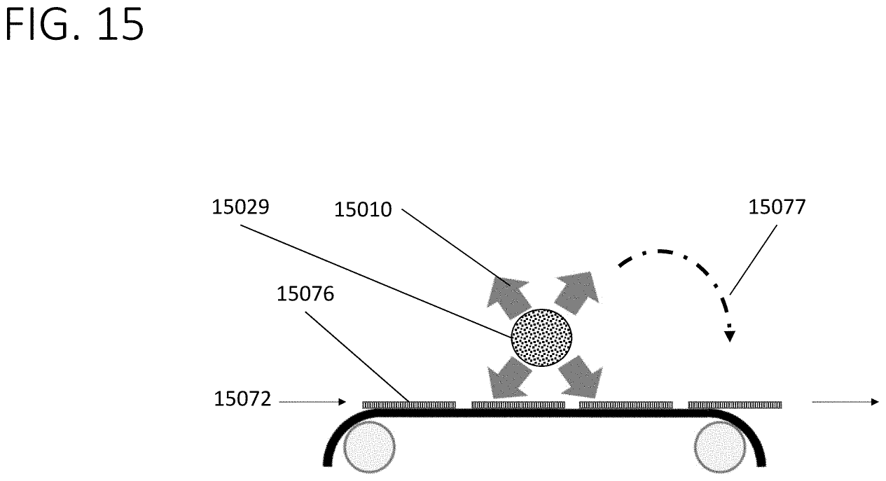

FIG. 15 is a schematic illustration of the application of a radial magnetron to a traditional in-line conveyance substrate processing station highlighting the IMPULSE®+Positive Kick™ enhanced plasma transport to the substrates. The radial magnetron 15029 is placed over an in-line conveyance with discrete conveyed substrates 15076. A portion of the particle flux 15010, due to its high ionization fraction from IMPULSE® operation, can be directed 15077 towards the discrete conveyed substrates 15076 with suitable electric field orientation, biasing, and vacuum chamber ground plane location.

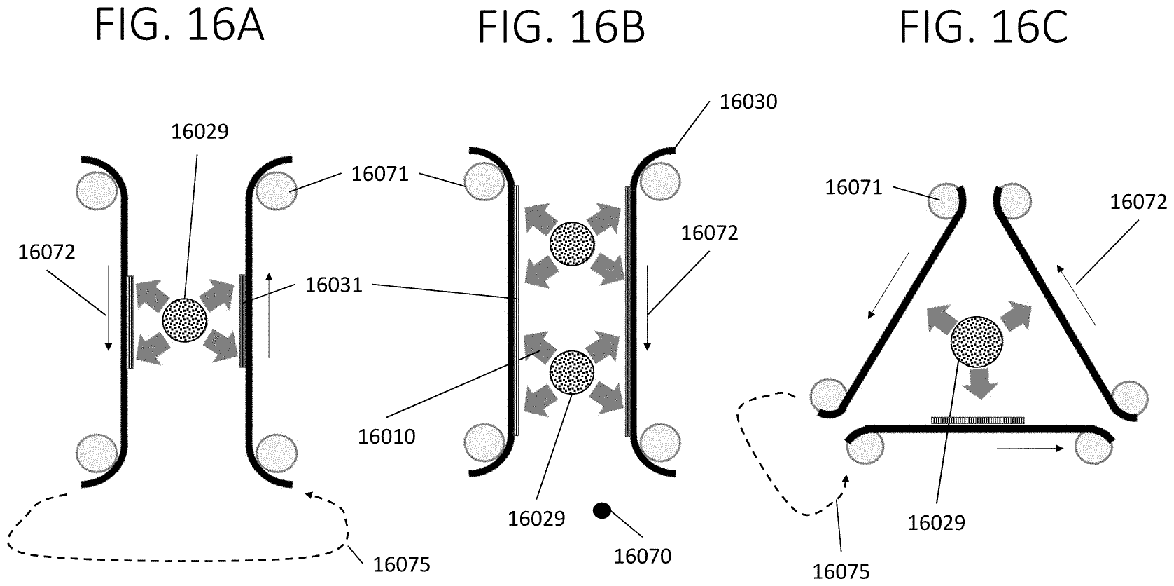

FIG. 16A is a schematic illustration of the application of a radial magnetron for in-line roll-to-roll and web coating where the substrate is transported relative to the radial magnetron and can be guided proximal to the radial magnetron for greater utilization efficiency. In FIG. 16A, a radial magnetron 16029 is situated between a roll-to-roll substrate system 16071 that guides the substrate 16030 along a web coater path 16075 with motion 16072 proximal to the radial magnetron 16029 to direct the particle flux 16010 onto the substrate 16030 to create surface modification and thin-film coating 16031.

FIG. 16B further depicts the application of multiple radial magnetrons 16029 to provide high-rate continuous roll-to-roll thin-film coating 16031 with the potential addition of auxiliary anode 16070 return electrodes for insulating or large-area substrates.

FIG. 16C further depicts the routing a web coater path 16075 of a flexible substrate 16030 around a single radial magnetron 16029 to maximize the utilization of sputtered material, and can be daisy chained with additional radial magnetrons for multi-layer coatings and in-line radial magnetron swap. The system illustrated in FIG. 16C could be expanded to many more radial magnetrons for large-scale printing and coating applications for thin-films on plastics, glass, metal, etc.

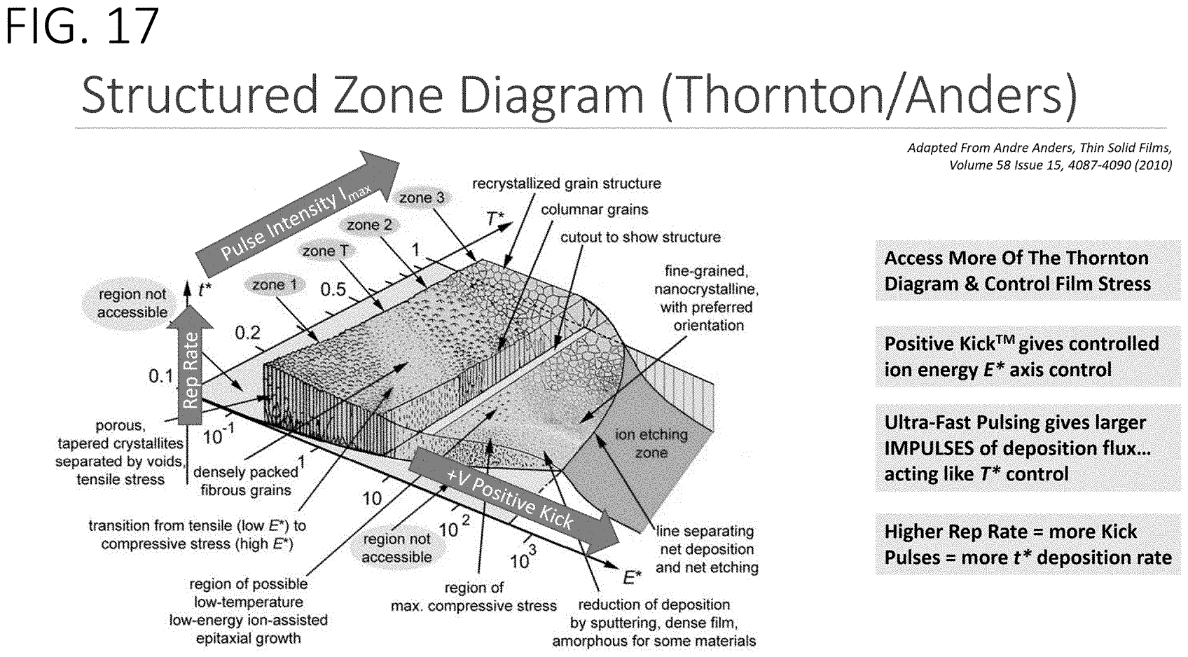

FIG. 17 illustratively depicts an example structure zone diagram with two independent axes for effective temperature (T*) and effective sputter particle energy (E*) that are addressable with the IMPULSE® and Positive Kick™. FIG. 19 expands on the control of thin-film microstructure and morphology via illustration of the Andre Anders' modified Thornton Structure Zone Diagram for generalized energetic condensation. Adjustment of the HiPIMS pulse amplitude, pulse width, timing, peak current density, repetition rate and pressure for a given substrate-to-sputter target distance, magnetic field geometry and field distribution, allows control over the main pulse particle flux (T*) which is approximate as a thermal spike. More intense short pulses with higher particle loading over shorter periods has a high temperature effect allowing the deposited material to equilibrate and adjust towards fibrous transitional grains (zone T), columnar grains (zone 2) and recrystallized grain structure (zone 3). Adjustment of the positive kick pulse amplitude, short/long kick pulse, onset delay and any super kick effect for RF-like oscillations for a given magnetic field, cusp magnetic null geometry, pressure and available plasma resulting from the main IMPULSE® HiPIMS pulse will allow adjustment of the effective energy (E*) and adjustment of the thin-film microstructure and morphology. Essentially controlling the IMPULSE® and the positive kick allows movement all over the Anders/Thornton SZD, even achieving fine-grained nanocrystalline films with preferred orientation and region of low-temperature low-energy ion-assisted epitaxial growth and dense, amorphous glassy films. The process engineer can move around the SZD to achieve tensile/compressive stress control, columnar growth vs. nanocrystalline with preferred orientation, etc.

In view of the many possible embodiments to which the principles of this disclosure may be applied, it should be recognized that the examples described herein with respect to the drawing figures are meant to be illustrative only and should not be taken as limiting the scope of the disclosure. For example, those of skill in the art will recognize that the elements of the illustrative examples depicted in functional blocks and depicted structures may be implemented in a wide variety of electronic circuitry and physical structures as would be understood by those skilled in the art. Thus, the illustrative examples can be modified in arrangement and detail without departing from the spirit of the invention. Therefore, the invention as described herein contemplates all such embodiments as may come within the scope of the following claims and equivalents thereof.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Exemplary embodiments are described herein known to the inventors for carrying out the invention. Variations of these embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A radial magnetron system for plasma surface modification and deposition of high-quality coatings for multi-dimensional structures, the radial magnetron system comprising:
an axial electrode;
a target material disposed on a portion of the axial electrode;
an applied potential from an external electrical power source;
a high-current contact attached to the axial electrode for the applied potential;
a primary permanent magnet assembly comprising individual magnetic material elements configured to produce a target-region magnetic field for generating a Hall-effect dense plasma region under application of the applied potential to the axial electrode;
a magnet substrate that supports the primary permanent magnet assembly within the axial electrode
wherein the magnet substrate is configured to provide a passageway for cooling the primary permanent magnet assembly and the axial electrode;

2. The system of claim 1, wherein the system further comprises at least one slotted bushing that maintains concentric orientation of the primary permanent magnet assembly relative to the axial electrode.

3. The system of claim 1, wherein the magnet substrate is configured to allow rotation of the primary permanent magnet assembly.

4. The system of claim 1, wherein the magnet substrate is configured to allow axial-longitudinal displacement of the primary permanent magnet assembly.

5. The system of claim 1, wherein the system further comprises a secondary internal permanent magnet assembly coupled to the magnet substrate and configured to allow applied motion from a secondary external magnet assembly.

6. The system of claim 5, wherein the system further comprises an isolation support configured to galvanically isolate the primary permanent magnetic assembly from the secondary internal permanent magnet assembly.

7. The system of claim 1, further comprising an end cap wherein the end cap is configured to rotatably support the magnet substrate.

8. The system of claim 1, further comprising an end cap wherein the end cap is configured to accommodate a coolant return passage.

9. The system of claim 1, wherein the axial electrode is substantially hollow cylindrical vessel.

10. The system of claim 1, wherein the primary permanent magnet assembly is segmented by gaps between discrete individual permanent magnetic field sources along the perimeter of the axial electrode.

11. The system of claim 3, wherein the system supports in-process rotation of the primary permanent magnet assembly.

12. The system of claim 4, wherein the system supports in-process axial-longitudinal displacement of the primary permanent magnet assembly.

13. The system of claim 1, wherein the external electrical power source further comprises field-generating electronic circuitry configured to perform:
generating a high-power pulsed plasma magnetron discharge with a high-current negative direct current (DC) pulse applied to the axial electrode, and
generating a configurable sustained positive voltage kick pulse provided to the axial electrode after terminating the negative DC pulse; and
wherein during the generating, program processor configured logic circuitry issues a control signal to control at least one kick pulse property of the sustained positive voltage kick pulse taken from the group consisting of: onset delay, duration, amplitude, and frequency including modulation thereof.

14. The system of claim 13, wherein the system is configured to modify a surface through material etching and material deposition during a single continuous production process.

15. The system of claim 1, further comprising a vacuum chamber, gas management, pumping, a fixture to hold a substrate to be coated relative to a radial magnetron, a thermal management system, and control electronics.

16. The system of claim 15, further comprising an actuator to affect position of a radial magnetron in relation to the vacuum chamber.

17. A batch coating system for depositing high-quality films on multiple surface treatment structures, the system comprising:
a vacuum chamber assembly comprising a vacuum chamber, gas management system, and vacuum pumping system;
a radial magnetron comprising a target material;
an external electrical power source, and
a mounting structure to hold multiple surface treatment structures;
wherein the mounting structure is interposed between the radial magnetron and the vacuum chamber,
wherein, during operation, the multiple surface treatment structures are treated using plasma generated in a plasma generating zone proximate the radial magnetron,
wherein the external electrical power source further comprises field-generating electronic circuitry configured to perform:
generating a high-power pulsed plasma magnetron discharge with a high-current negative direct current (DC) pulse applied to the axial electrode, and
generating a configurable sustained positive voltage kick pulse provided to the axial electrode after terminating the negative DC pulse; and
wherein during the generating, program processor configured logic circuitry issues a control signal to control at least one kick pulse property of the sustained positive voltage kick pulse taken from the group consisting of: onset delay, duration, amplitude, and frequency including modulation thereof.

18. A roll-to-roll web coating system for depositing high-quality films simultaneously on multiple flexible substrate surfaces from a single radial magnetron, the system comprising:
a vacuum chamber assembly comprising a vacuum chamber, gas management system, and vacuum pumping system;
a radial magnetron comprising a target material;
an external electrical power source; and
a roll-to-roll web conveyance system for simultaneously transporting a substrate into a plasma treatment zone,
wherein, in operation, the radial magnetron generates a plasma field for creating the plasma treatment zone,
wherein the external electrical power source further comprises field-generating electronic circuitry configured to perform:
generating a high-power pulsed plasma magnetron discharge with a high-current negative direct current (DC) pulse applied to the axial electrode, and
generating a configurable sustained positive voltage kick pulse provided to the axial electrode after terminating the negative DC pulse; and
wherein during the generating, program processor configured logic circuitry issues a control signal to control at least one kick pulse property of the sustained positive voltage kick pulse taken from the group consisting of: onset delay, duration, amplitude, and frequency including modulation thereof.
